(19) United States
(12) Patent Application Publication
(10) Pub. No.: US 2008/0006201 A1
(43) Pub. Date: Jan. 10, 2008

(54) Method of growing gallium nitride crystal

(75) Inventors: Ryu Hirota, Hyogo (JP); Kensaku Motoki, Hyogo (JP); Seiji Nakahata, Hyogo (JP); Takuji Okahisa, Hyogo (JP); Koji Uematsu, Hyogo (JP)

Correspondence Address: MCDERMOTT WILL & EMERY LLP, 600 13TH STREET, N.W., WASHINGTON, DC, 20005-3096, US

(73) Assignee: SUMITOMO ELECTRIC INDUSTRIES, LTD.

(21) Appl. No.: 11/826,798

(22) Filed: Jul. 18, 2007

Related U.S. Application Data
(63) Continuation-in-part of application No. 10/933,291, filed on Sep. 3, 2004.
Application No. 10/933,291 is a continuation-in-part of application No. 10/700,495, filed on Nov. 5, 2003, now Pat. No. 7,112,826.
Application No. 10/700,495 is a division of application No. 10/246,559, filed on Sep. 19, 2002, now Pat. No. 6,667,184.
(63) Continuation-in-part of application No. 10/936,512, filed on Sep. 9, 2004.
Application No. 10/936,512 is a continuation-in-part of application No. 10/265,719, filed on Oct. 8, 2002, now Pat. No. 7,087,114.

(30) Foreign Application Priority Data
Aug. 2, 2006 (JP) 210506/2006
Sep. 19, 2001 (JP) 2001-284323
Oct. 9, 2001 (JP) 2001-311018
Sep. 17, 2002 (JP) 2002-269387

(51) Int. Cl. C30B 25/04

(52) U.S. Cl. 117/90; 117/89

(57) ABSTRACT

The facet growth method grows GaN crystals by preparing an undersubstrate, forming a dotmask or a stripemask on the undersubstrate, growing GaN in vapor phase, causing GaN growth on exposed parts, suppressing GaN from growing on masks, inducing facets starting from edges of the masks and rising to tops of GaN crystals on exposed parts, maintaining the facets, making defect accumulating regions H on masked parts. attracting dislocations into the defect accumulating regions H on masks and reducing dislocation density of the surrounding GaN crystals on exposed parts. The defect accumulating regions H on masks have four types. The best of the defect accumulating regions H is an inversion region J. Occurrence of the inversion regions J requires preceding appearance of beaks with inversion orientation on the facets. Sufficient inversion regions J are produced at an initial stage by maintaining the temperature Tj at 900° C. to 990° C. without fail. Allowable inversion regions J beaks are produced at an initial stage by the sets of temperatures T(K) and growing speeds Vj (μm/h) satisfying −4.39×10⁵/T+3.87×10²<Vj<−7.36×10⁵/T+7.37×10².

### RELATED APPLICATIONS

This application is a Continuation-In-Part Application based on U.S. patent application Ser. No. 10/933,291 filed Sep. 3, 2004 and U.S. patent application Ser. No. 10/936,512 filed Sep. 9, 2004.

This application claims priority to Japanese Patent Application No. 2006-210506 filed Aug. 2, 2006.

### FIELD OF THE INVENTION

Gallium nitride (GaN) type blue/violet semiconductor lasers will be used for reading-out data of the next generation large capacity photodiscs. Putting GaN type blue/violet laser diodes (LDs) into practice requires gallium nitride crystal substrates of high quality. This invention relates to a method of growing a high quality gallium nitride crystal (GaN) for substrate wafers on which blue/violet LDs are made. In addition to production of GaN blue/violet LDs, the GaN substrate wafers will be useful for producing light emitting devices (light emitting diodes LEDs, laser diodes LDs of other colors), electronics devices (rectifiers, bipolar transistors, field effect transistors FETs, high electron mobility transistors HEMTs, and so on), semiconductor sensors (thermometers, pressure sensors, radioactive ray sensors, visible/ultraviolet photodetectors, and so on), surface acoustic wave devices SAWs, accelerator sensors, MEMS devices, piezoelectric oscillators, resonators, piezoelectric actuators, and so on.

### BACKGROUND OF THE INVENTION

GaN type laser diodes emitting 405 nm wavelength light will be used for reading-out of data of high density photodiscs. Blue/violet LEDs (light emitting diodes) are made by piling GaN, InGaN, etc., films on sapphire (Al₂O₃) substrates. Sapphire is different from gallium nitride (GaN) in lattice constant. The difference of the lattice constants generates high density of dislocations. In the case of on-sapphire GaN light emitting diodes (LEDs), low current density does not proliferated dislocations. GaN LEDs on sapphire substrates have a long lifetime. But in the case of on-sapphire GaN laser diodes (LDs), high current density will proliferate dislocations and rapidly degenerate on-sapphire GaN LDs. Sapphire substrates are unsuitable for GaN LDs which have large current density. Unlike GaN LEDs, on-sapphire blue/violet GaN LDs have not been put into practice yet.

There is no material which has a lattice constant sufficiently close to gallium nitride (GaN). It turns out that the best substrate on which GaN films are grown without misfit is a GaN substrate. Realization of GaN blue/violet LDs requires low dislocation density GaN substrates with high quality.

However, crystal growth of GaN in liquid phase is difficult. Heating GaN solid does not make a GaN melt. A flux method which grows GaN solid in liquid phase is yet on the stage of research. No practical size GaN crystals with a diameter larger than 2 inches have been produced by liquid phase growth. Vapor phase growth which grows GaN crystal from vapor phase has been tried for producing high quality GaN substrate crystals having sizes enough to satisfy practical use.

The inventors of the present invention have contrived and proposed methods of making a thick freestanding GaN substrate crystal by forming masks on a foreign material undersubstrate, growing a thick GaN crystal on the masked foreign material undersubstrate in vapor phase and removing the undersubstrate.

(1) WO99/23693 of the present inventors proposed a method of producing a freestanding GaN substrate crystal by forming a stripemask with stripe windows or a dotmask with dot windows on a GaAs undersubstrate, growing a thick GaN crystal on the masked GaAs undersubstrate and removing the GaAs undersubstrate. This masks have wider masked parts and narrower exposed parts (windows). The masks are masked part prevalent masks. GaN nuclei happen only in exposed parts (windows) on the undersubstrate. The mask prevents GaN nuclei from happening. When the nuclei dilate into unified GaN grains on the GaAs undersubstrate in the windows, the GaN grains overstep on masks. The GaN grains grow in horizontal directions on masks. Movements of dislocations accompany the growth. In parallel with the growing direction, dislocations extend in the horizontal directions on masks. GaN crystals expanding from neighboring windows collide with each other at the middles between two neighboring windows on masks. Dislocations collide at the same time. Then the growing direction of GaN turns upward. Accompanying the growth, dislocations also begin to expand upward. The turn decreases dislocations. Two changes of directions decreased the number of dislocations in the ELO method. Afterward the ELO grows the crystal in the vertical direction with maintaining the flat C-plane surface.

(1) WO99/23693 which decreases dislocations by growing crystals on masks in horizontal directions is an improvement of the ELO methods (Epitaxial Lateral Overgrowth). A conventional ELO method prepares a GaN film on a sapphire undersubstrate, deposits a SiO₂ film on the GaN film, forms a mask by etching small linear or dotted windows on the mask, grows GaN crystals on the GaN film exposed via windows and allows the GaN crystals to overstep on the mask. (1) WO99/23693 forms a mask directly on a GaAs undersubstrate without GaN film and grows GaN crystals on the GaAs undersubstrate exposed via the windows, which is called HELO (Hetero-Epitaxial Lateral Overgrowth) method. The GaN crystal which is made by (1) WO99/23693 has lowered dislocation density. (1) proposed a further growth of making use of the GaN crystal as a seed of growing a new thick GaN crystal thereupon. The thick GaN crystal is sliced into several GaN wafers in the direction vertical to the growing direction in (1) WO99/23693. There are an MOCVD method, an MOC method, an HVPE method and a sublimation method for vapor phase growth of GaN. (1) mentions that the HVPE method has an advantage of the fastest growing speed among the known vapor phase methods.

However the GaN crystals produced by the ELO methods or the HELO method of (1) have high density of dislocations and poor quality. Production of good devices requires good quality GaN substrates. Existence of wide low defect density regions is indispensable for GaN substrates served for mass production of devices. The Inventors of the present invention proposed a contrivance of (2) Japanese Patent Laying Open 2001-102307 for reducing dislocation density of GaN substrates.

The dislocation reduction method of (2) Japanese Patent Laying Open 2001-102307 grows a thick GaN crystal, sweeps dislocations in the GaN crystal into definite spots and decreases dislocations in other regions except the spots.

As shown in FIG. 1(a), (2) Japanese Patent Laying Open 2001-102307 grows a GaN crystal by building three dimensional facet structures for example, inverse hexagonal cone pits 5 composed of facets 6, maintaining the facet pits 5, and not burying the facets pits 5 till the end of the growth. FIGS. 1(a) and (b) show a part of a crystal 4 surface having an inverse hexagonal conical pit 5. The surface of a growing GaN is not perfectly flat. The surface has pits here and there. The flat top is a C-plane 7. GaN crystals grow upward in the direction of a c-axis on the flat top (C-plane) 7. GaN crystals grow slantingly upward in pits composed of inclining facets. Some pits are hexagonal. Other pits are dodecagonal. In the case of a hexagonal cone, a facet meets with neighboring facets at 120 degrees. Neighboring facets 6 and 6 join at a boundary line 8. The bottom of a pit at which the boundary lines converge is a spot at which feet of facets assemble.

A normal (line) is defined as a straight line extending in the direction vertical to an object plane. A c-axis is a normal to a C-plane. Crystals grow on a plane in the direction of a normal standing on the plane. An average growth direction is the c-axis direction on the C-plane surface. On a facet, crystal grows in a slanting direction normal to the facet. Θ is an inclination angle of a facet to the C-plane. A normal standing on the facet inclines at Θ to the c-axis. (2) does not bury the pits of facets. Non-burying of pits means anisotropic growing speeds. The top surface (C-plane) growing speed is denoted by u. The facet growing speed v is denoted by v=u cos Θ. The growing speed v of a facet is smaller than the C-plane growing speed u. Thus the facet growth means anisotropy of growing speeds.

Dislocations extend in parallel with the growing direction. The speed of extending of a dislocation is equal to the speed of growing of the facet on which the dislocation lies. Since v<u (the growing speed of facets is slower than the growing speed of the C-plane), dislocations existing on a facet move to boundary 8 with the progress of growth. Dislocations are swept on the facets. The dislocations reaching the boundaries sink along the boundary 8 to the bottom due to the slow growing speed of facets. Planar defect assemblies 10 are built below the boundaries 8, as shown in FIG. 1(b). The falling dislocations assemble at the bottom 9 of the pit. Since dislocations swept away from the facets gather at the bottom, linear defect assemblies 11 are formed at the bottoms 9 of pits.

The dislocations D which have been on facets are attracted and assembled into the planar defect assemblies 10 or linear defect assemblies 11. Dislocations D on the facets 6 decrease. The regions below the facets 6 become low dislocation density. The other dislocations which have been on flat C-planes 7 are attracted to neighboring facets 6. The dislocations moved from the C-planes 7 to the facets 6 also move to boundaries 8 and to the bottoms 9 by the facet growth. When facet pits 5 exist at high density, dislocations on the facets 6 or the C-planes 7 are swept into the under-boundary regions 10 or under-pit regions 11. The dislocations which exist on other regions are reduced. The dislocation reduction effect by facets is maintained throughout the crystal growth by not burying but keeping the facet pits 5 till the end of the growth.

FIG. 2 demonstrates the dislocation reduction effect by the facet growth in a plan view of a pit on a fact growing GaN surface. When the facet is maintained, the direction of crystal growth on a facet 6 is parallel to a normal standing on the facet 6. Dislocations also extend in the normal direction on the facet 6. FIG. 2 clarifies that movements of dislocations are parallel to growth directions on a facet. When the directions of dislocation movement are projected on a facet 6 in the plan view, the extension directions are parallel to the direction of the inclination of the facet 6. The dislocation soon arrives at a boundary 8. Then the dislocation D goes inward along the boundary 8. Inward movement means a relative slanting fall of the dislocation along the boundary 8. In reality dislocations extend laterally or slanting upwardly. Since v<u, dislocations seem to descend along the boundaries 8 from a reference plane fixed on the growing surface. Some dislocations descending along the boundaries make planar defect assemblies hanging below the boundaries. Other dislocations are assembled at the bottoms 9 of the pits 5. The dislocations make defect assembling bundles 11 following the bottoms 9.

The Inventors have noticed the facet growth method having the following problems.

Problem (1): When the GaN crystal grows thicker with assembling dislocations into defect accumulating regions H, once gathered dislocations have a tendency of escaping from the defect accumulating regions at the bottoms of pits as hazy dispersion. The release of dislocations is explained by referring to FIG. 3(1) and FIG. 3(2). FIG. 3(1) is a sectional view of a pit 5 of facets 6 for showing arrested dislocations D forming a linear dislocation assembling bundle 11 at the bottom 9 of the pit 5 at an early stage of the facet growth. Dislocations in the surrounding regions 4 below facets 6 and C-planes 7 are decreased. FIG. 3(2) shows hazy dispersion 13 of once arrested dislocations D escaping from the bundle 11. The hazy dispersion 13 signifies that the defect assembling bundle 11 has a weak, insufficient power of arresting dislocations.

Problem (2): Positions of the defect assembling bundles 11 are determined by chance. The bundles 11 happen at random. The positions of the bundles 11 cannot be predetermined. The positions of the dislocation assembling bundles are uncontrollable.

The reason of problem (2) derives from accidental occurrence of pits 5 of facets 6 and defect assembling bundles 11. It is desirable to predetermine the positions of the defect assembling bundles 11. The solution of Problem (1) requires to build unpenetrable barriers on the dislocation assembling bundles.

For solving the problems, the Inventors have made contrivances. The inventors had thought that the reason of hazy dispersion occurrence 13 as shown in FIG. 3(2) originates from the fact that the center bottoms 9 of the pits 5 of facets 6 gather dislocations without annihilating or arresting dislocations.

Thus Problem (1) shall be solved by adding a dislocation annihilating/accommodating device to the defect assembling bundles. FIGS. 4(1) and (2) show the solution of Problem (1). A plurality of isolated dot masks 23 made from a material capable of inhibiting GaN from epitaxially growing are formed in a regular repetition pattern on an undersubstrate. Exposed parts of the undersubstrate allow GaN to start crystal growth. C-plane growth having a C-plane top 27 prevails on the exposed parts. GaN crystals 24 grow on the exposed parts 21.

However crystal growth does not start at the parts on the wide masks 23 soon. Crystal growth continues on exposed parts. Facets 26 which are slanting planes starting from verges of masks happen. Pits 25 being composed of facets and having bottoms 29 at masks 23 are produced. Without burying the pits 25, the crystal growth continues with maintaining the facets and the facet pits till the end of growth. Dislocations are swept by facets 26 to the pit bottoms 29. The bottoms 29 of the pits 25 coincide with the masks 23. Dislocations swept away are gathered at the regions below the pit bottoms 29 above the masks 23. The above-mask, below-bottom regions become defect accumulating regions H. The defect accumulating region H consists of a grain boundary K and a core S. H=S+K.

Thus (3) Japanese Patent Laying Open No. 2003-165799 produces defect accumulating regions H enclosed by grain boundaries K as a dislocation annihilation/accommodation device by forming masks 23 on an undersubstrate 21. A mask 23, a defect accumulating region H and a pit bottom 29 align in a vertical line in the facet-growing GaN crystal. The masks 23 determine the positions of the defect accumulating regions H and the pits 25. The regions below the facets 26 on exposed parts become low defect density single crystal regions Z. The other region below the C-plane on exposed parts becomes a C-plane growth regions Y.

Dislocations are continually assembling into defect accumulating regions H. The defect accumulating region H has a definite volume and is enclosed by a grain boundary K. The dislocations once arrested do not escape from the defect accumulating region H due to the grain boundary K. The grain boundary K has another function of annihilating dislocations. The crystal enclosed by the grain boundary K is a core S. The core S has functions of accumulating dislocations and annihilating dislocations. It is important for (3) Japanese Patent Laying Open No. 2003-165799 to positively produce the regions H consisting of a grain boundary K and a core and gathering dislocations by masks 23. The surface rises from the dotted line in FIG. 4(1) to the solid line of FIG. 4(2). Dislocations are firmly arrested in the defect accumulating region H. Dislocations do not escape from Hs. No hazy dispersion of releasing dislocations happens. The defect accumulating regions can maintain the state of accommodating dislocations till the end. The problem of the hazy dispersion of dislocations is solved.

At first it was not clear for the inventors of (3) what kinds of nature the defect accumulating regions H have. Furthermore the property of the defect accumulating regions H is not uniquely determined. Sometimes the defect accumulating region H is a polycrystal. Sometimes the defect accumulating region H is a single crystal having crystal axes inclining at a slight angle to the other regions of the growing crystal. In these cases of polycrystal or inclining axis single crystal, the above-mask defect accumulating regions H are insufficient to work as a defect annihilating/accommodating device. Sometimes no defect accumulating regions happen on masks. In this case, the facets 26 penetrate and grow on the mask 26. The pits are only shallow cavities. The regions above the masks do not act as a defect annihilating/accommodating device. Sometimes the defect accumulating region H is a single crystal with the c-axis which is inverse to the c-axis of the surrounding crystals Z and Y. Defect accumulating regions H have manifold variations. What types of defect accumulating region appear on masks depends upon the conditions of growth.

The best of the defect accumulating regions is the c-axis inversion single crystal which has a c-axis [0001] entirely inverse to the c-axis [0001] of the surrounding regions Z and Y. The region is named as an orientation inversion region, a c-axis inversion region, a polarity-inversion region or an inversion region J. All are synonyms. When the orientation inversion region is made as a defect accumulating region H, the orientation is inversely rotated at an interface. Thus continually definite grain boundary K is produced between the inner inversion defect accumulating region H and outer single crystal regions Z and Y. The continual grain boundary K has a strong function of annihilating and accommodating dislocations. A cavity, a polycrystal or a c-axis inclining regions have insufficient defect annihilating/accommodating function.

The surrounding regions are also divided into two categories. The regions growing below facets on exposed parts are named “low defect density single crystal regions” Z. The regions growing below the C-planes on exposed parts are called “C-plane growth regions” Y. Both Z and Y are single crystals with common orientation and common c-axes and low defect density. However, Z and Y are different in electrical property. The C-plane growth regions Y have high resistivity. The low defect density single crystal regions Z have low resistivity.

The low defect density single crystal regions Z and the C-plane growth regions Y are single crystals having an upward directing c-axis [0001]. The inversion regions J, which are the best type of the defect accumulating regions H, have inverse single crystals having a downward directing c-axis [0001]. Orientation is inverse. Definite, stable, continual grain boundaries K are produced by the inversion of orientation between the inversion regions J and the surrounding regions Z. The grain boundaries K have effective functions of annihilating and arresting dislocations. Thus it is an advantage for the inversion regions J to establish grain boundaries K between the defect accumulating region H and the surroundings Z. The grain boundary K enables the defect accumulating region H to discern the inner space S from the outer space Z.

The most effective way in reducing dislocation density is to produce the (polarity, orientation) inversion regions J on masks as defect accumulating regions H.

The growing speed of defect accumulating regions H is lower than the speed of the surrounding regions Z and Y. The defect accumulating regions H become cavities. The defect accumulating regions H can stably stay at bottoms of pits or valleys. The defect accumulating regions H stay at the bottoms of inverse hexagonal cone pits.

Dislocations are annihilated with a high efficiency at grain boundaries K enclosing the defect accumulating regions H. The grain boundary prohibits once gathered dislocations from escaping from H. The grain boundary inhibits hazy dispersion from occurring. The grain boundaries enable us to make low defect density GaN crystals which encapsulate dislocations within the defect accumulating regions H.

The regions of generating the defect accumulating regions H are possible to be fixed at arbitrary positions. The defect accumulating regions H do not accidentally happen to occur but are formed at predetermined positions, whereby it is possible to make good quality GaN crystals with regularly aligning defect accumulating regions H.

Shapes of the defect accumulating regions H have some different versions. For example, a set of regularly aligning isolated dots is one version. Aforementioned (3) Japanese Patent Laying Open No. 2003-165799 has proposed GaN crystals having such dotted defect accumulating regions.

FIG. 10(1) shows a plan view of an example of a dotmask. Many regularly aligning isolated mask dots M are produced upon an undersubstrate U. When GaN is grown on the dotmasked undersubstrate, low defect density good quality GaN crystals are made upon wide exposed parts. Defect accumulating regions H occur on the regularly aligning isolated dots M. Facet pits whose bottoms correspond to tops of the defect accumulating regions H are yielded. The regions below the facets become low defect density single crystal regions Z. Out of the facets, a continual C-plane growth region Y is grown.

FIG. 6(2) shows a perspective view of a part of the GaN crystal grown on the dotmask-formed undersubstrate U. The flat top surface is a C-plane. The regions below the C-plane is C-plane growth region Y. Many pits composed of facets F are produced just above the mask dots M on the surface. The regions just beneath the facets F are low defect density single crystal regions Z. Bottoms of the facet pits coincide with tops of defect accumulating regions H. The defect accumulating regions H are made upon the mask dots M. Since the dotmask-grown GaN crystal has many deep cavities (pits) on the surface, the surface should be ground by more than the depth of the cavities for making a flat surface.

FIG. 10(2) shows a plan view of a part of a freestanding flat GaN substrate crystal obtained by eliminating the undersubstrate U from the bottom of the as-grown GaN crystal of FIG. 6(2) and grinding the rugged surface of the GaN crystal. Comparing FIG. 10(2) with FIG. 10(1) confirms defect accumulating regions H have been made on mask dots M. Enclosing the defect accumulating region H, low defect density single crystal regions Z and a C-plane growth region Y build a repeating concentric structure (YZH).

Another type of masks is a stripemask which has many parallel mask strips for making stripe structure type GaN crystals. (4) Japanese Patent Laying Open NO. 2003-183100 proposed a GaN crystal having a stripe structure. An example of a stripemask is shown in FIG. 8(1). A plurality of parallel mask stripes M are formed upon an undersubstrate U. The width of a stripe M is s. The pitch of stripes is p.

FIG. 6(1) demonstrates a GaN crystal grown on the stripemask-carrying undersubstrate (FIG. 8(1)). Parallel mountain ranges composed of low defect density single crystals Z are produced on exposed parts of the undersubstrate U. Slopes of the mountains are facets F. A mountain range is composed of two conjugate facets F. Sometimes flat tops of C-planes appear between two conjugate facets F. V-grooves between mountains are defect accumulating regions H, which are produced upon the mask stripes M. A freestanding GaN substrate is obtained by removing the undersubstrate U and grinding the superficial mountains. FIG. 8(2) is a plan view of a GaN wafer by separating the GaN crystal from the undersubstrate U and grinding/polishing the rugged surface. The GaN wafer has a parallel HZYZHZYZH . . . structure.

FIG. 5 demonstrates the on-stripemask facet growth method. Parallel mask stripes M are formed on an undersubstrate U (FIG. 5(1) equivalent to FIG. 8(1)). The mask stripe M extends in the direction vertical to the sheet. GaN is grown in vapor phase on the stripemask-covered undersubstrate U. The undersubstrate U allows GaN nuclei to happen. The mask stripes M prohibit GaN from producing nuclei. No GaN crystal growth happens on stripes M. GaN crystals grow on exposed parts in the direction of the c-axis. FIG. 5(2) demonstrates the initial step of the GaN growth. The flat top of the growing GaN crystal is C-plane. The mask has a function of prohibiting GaN from epitaxially growing. The upper space above the mask M is vacant at the initial stage.

Growing GaN crystals come close to verges of masks and fill the exposed parts. Slants expanding upward from the verges of the masks to the C-plane tops are facets F. A further progress of growth forces GaN crystals to pile also on the masks M. Delay of growth on the mask makes a cavity at the mask M. The region on the mask M is a c-axis inversion defect accumulating region H. On the c-axis inversion defect accumulating region, other kind of facets F′, F′ having a smaller inclination lie. The facets F′ has an inclination common to the upper slope of the small polarity inversion crystals Q appearing in FIG. 7(3) and FIG. 7(4). The crystals grown on exposed parts below the facets F are low defect density single crystal regions Z. The crystals grown on exposed parts below the flat C-plane are C-plane growth regions Y. The interfaces between the defect accumulating regions H and the low defect density single crystal regions Z are grain boundaries K. The interfaces between the steeper facets F and the milder facets F′ coincide with the tops of the grain boundaries K.

Since mask stripes M are plural and parallel, defect accumulating regions H form parallel valleys on the stripes M. The intermediate portions between neighboring stripes become low defect density single crystal regions Z or C-plane growth regions Y. The low defect density single crystal regions Z and the C-plane growth regions Y make parallel mountains. On the stripemask case, the facet growth makes a structure with repeating parallel valleys and mountains. When no C-plane growth region happens, sharp mountain ranges (consisting of Z) without flat tops are produced. When C-plane growth regions occur, the mountains (composed of Z and Y) have blunt tops. The above is the stripemask case.

The formation of Z, Y, and H on the dotmask-carrying undersubstrate is similar to the formation of Z, Y and H on the stripemasked undersubstrate. In the dotmask case, isolated facet pits having a center of a mask dot are yielded. The hexagonal regions following the facets F on an exposed part are low defect density single crystal regions Z. The other region below the C-plane surface on an exposed part is a C-plane region Y, which is a continual region. Z and Y are both low defect density single crystals.

The regions upon the mask dots M become defect accumulating regions H. There are several different types in defect accumulating regions H. One type is a polycrystal (P). Another type is a c-axis inclining single crystal (A). Another type is a c-axis inverting single crystal (J). “c-axis inversion”, “polarity inversion”, “orientation inversion” or “inversion” are all synonyms for indicating an orientation inversion region J. Sometimes no defect accumulating region happens (O) on the dots (M). Thus the defect accumulating regions H have four alternatives O, A, P and J.

When inversion regions J are borne on masks (H=J), the defect accumulating region H(=J) has an inverse Ga-surface and an inverse N-surface. The c-axis is inverse in J. The orientation is inverse in J. The polarity is inverse in J. The inversion region H is named “polarity inversion” region by the inventors. In general compound semiconductors are polarized crystal. GaN has wurtzite structure composed of Ga atom layers and N-atom layers alternately piling on each other at different intervals in the c-axis direction. The different interval allots GaN with polarity in the direction of the c-axis. The c-axis inversion regions J (H=J) has a c-axis by 180 degrees inverse to the surrounding GaN crystals.

The interface between Z and H is a grain boundary K. Tops of the inversion defect accumulating region H(=J) are milder facets F′ with an inclination angle smaller than the facet F above Z on the exposed parts. The grown GaN crystal has many isolated pits aligning in a C-plane surface. Sectional view of a pit of a dotmask-grown GaN seems to be similar to a section of a valley of a stripemask-grown GaN. In the dotmask-grown GaN, a defect accumulating region H on a dot is an isolated closed region. Facets appearing around H are mainly {11-22} and {1-101} planes. The masks M are seeds of the defect accumulating regions H.

The positions at which masks are formed on an undersubstrate at first determine the positions at which defect accumulating regions H occur in the vapor phase growth. The positions at which Z and Y happen are determined. The (1) Japanese patent Laying Open No. 2001-102307 (random)-relevant problem of undetermined, random positions of defect accumulating regions H is solved by forming masks on undersubstrates and making inversion regions J on masks.

The defect accumulating region H which is an inversion region J has a definite grain boundary K. The grain boundary K prevents once gathered dislocations from releasing again as hazy dispersion. Reformation of the masks enables the facet growths of (3) Japanese Patent Laying Open No. 2003-165799 and (4) Japanese Patent Laying Open NO. 2003-183100 to control the positions of defect accumulating regions H.

The facet growth methods succeed in determining the positions of Hs, Zs and Ys. Then a new matter rises to the surface. A defect accumulating region H sometimes makes a definite grain boundary and sometimes cannot make a continual definite grain boundary. Occurrence or non-occurrence of grain boundaries depends upon specific conditions. Even if a defect accumulating region H happens on a mask, the defect accumulating region H does not always become a 180 degree c-axis inversion region J. Sometimes the defect accumulating region H becomes a polycrystal (P). Otherwise the defect accumulating region H becomes a c-axis inclining single crystal (A) whose c-axis is different from the c-axis of the surroundings (Z and Y). Sometimes no defect accumulating region (O) happens. The regions on masks have four kinds of versions O, A, P and J.

When the defect accumulating regions H built on masks are polycrystals (P), some crystals have orientation similar to the surroundings Z. No definite orientation discrepancy happens between the partial crystals and the surroundings Z. No definite grain boundary occurs therebetween. When the defect accumulating region formed on masks is a single crystal with a c-axis inclining to the c-axis of the surroundings Z, some portion has orientation similar to the surrounding crystals Z. A definite, continual grain boundary K is not produced between H and Z. A vague grain boundary K has a weak power of arresting dislocations and is easy to allow dislocations to disperse. When the defect accumulating region H is a polarity inversion region J, the orientation of all the parts of H is different from the surroundings Z. A continual definite grain boundary K is surely produced between J and Z. The continual grain boundary K has a strong function of arresting and accommodating dislocations without releasing.

Without definite grain boundaries K, the defect accumulating regions H has a weak power inadequate to arrest and annihilate dislocations. Grain boundaries K are made by the on-mask orientation inversion regions J and the surrounding crystals with normal orientation. Thus the formation of inversion regions J on masks is ardently required to arrest, annihilate and accommodate dislocations firmly in the defect accumulating regions H. The inversion region J is the best alternative of the defect accumulating region H. An object of the present invention is to provide a reliable method of making inversion regions J on masks as defect accumulating regions H.

It is the best that inversion regions J are generated on masks as defect accumulating regions H. If GaN crystals with no or few inversion regions J are produced by the facet growth, once arrested dislocations in defect accumulating regions H will be released from the defect accumulating regions H as hazy dispersion. The surrounding regions will be not low defect density but high defect density GaN. When blue/violet GaN type LDs are produced on a high defect density GaN substrate, the yield of accepted products will be low. The GaN substrate will be useless. It is strongly desired to make inversion regions J on masks as defect accumulating regions H. A series of steps of causing inversion regions J on masks are in detail observed for clarifying the conditions of producing inversion regions J. The steps are explained by referring to FIG. 7(1)-(5).

Step (1): Step (1) forms masks M at positions for inducing defect accumulating regions H on a surface of an undersubstrate U. The material of the masks has a function of inhibiting GaN from epitaxially growing. The masks become seeds of the defect accumulating regions H. Thus a seed is a synonym of a mask. FIG. 7(1) denotes a part of an undersubstrate U covered with masks M. FIG. 7(1) shows only one mask stripe in brief, but many mask stripes M actually cover the undersubstrate U.

Step (2): Step (2) grows GaN on the masked undersubstrate in vapor phase. Exposed parts allow GaN nuclei to happen. Masks prevent GaN nuclei from occurring. GaN grows only on exposed parts. The GaN crystals have C-plane tops. Masks are not covered with GaN. Progress of growth is stopped at the verges of masks. GaN crystals do not overstep masks at an initial stage. Inclinations starting from the verges of masks and attaining to the top C-plane are formed as demonstrated in FIG. 7(2). The inclinations are some kinds of facets except C-plane. Facets confront each other across the mask. In many cases, the facets are {11-22} planes. When a stripemask M is formed on an undersubstrate, V-grooves are formed on masks extending in the direction vertical to paper. When a dotmask consisting of isolated dots is formed, isolated pits composed of facets are formed on masks. FIGS. 7(1)-(5) show the case of a stripemask. The steps are similar to the case of a dotmask.

Step (3): Small beaks Q and Q having c-axes of 180 degree inverting orientation appear midway on the inclinations of GaN facets whose growth is stopped at the lower ends by the edge of the mask, as shown in FIG. 7(3). The beaks Q have upper milder and lower steeper inclinations different from the facets F. It turns out that the beaks Q are c-axis inverting crystals (polarity inversion). If the beaks Q dilate, desired inversion regions J are generated on the dilated beaks Q.

Step (4): The progress of the crystal growth increases the number and volume of the inversion beaks Q grown on the facets F. The beaks Q join in series along the extensions of facets F. Trains of beaks are produced on the facets in the longitudinal direction. Each facet has a long beak train. A pair of inversion beaks Q and Q on confronting facets spread over a mask and cover the mask.

Step (5); A beak Q has a milder facet F′ on an upper side and a steeper facet on a lower side. The upper facets F′ are low inclination facets {11-2-6} or {11-2-5}.

Step (6): The polarity inversion beaks Q dilate in the horizontal and vertical directions. Tips of the beaks Q and Q collide with and couple with each other above the mask. As shown in FIG. 7(4), a bridge composed of the confronting beaks is formed between the paired facets. The bridges have c-axis inverting (orientation inversion) crystals. GaN grows on the bridges, having the same inversion orientation. Gaps between the bridge and the mask are filled with inversion crystals. The on-mask crystals are not made by depositing GaN directly on the mask but are made by piling GaN on the inversion bridges above the masks. The inversion regions J grow upward. The gap below the bridge is also filled with polarity inversion crystals.

Step (7): Collision parts J and J grow thicker with lattice misfit boundaries K′ therebetween. The lattice misfit boundaries K′ between J and J are different from the grain boundaries K between the polarity inversion region J and the low defect density single crystal regions Z. The polarity inversion regions J become defect accumulating regions H.

Step (8): As GaN crystals grow thick, dislocations in the GaN crystals are gathered from the surrounding GaN regions into the inversion regions J on the masks M through the growth of the slanting facets. A part of the dislocations gathered is annihilated at the grain boundaries K between the polarity inversion regions J and the low defect density single crystal regions Z or the cores S of the inversion regions J. Upward extending inversion regions J become defect accumulating regions H by gathering dislocations D. The rest of the dislocations are arrested and accommodated in the grain boundaries K and the cores S of the defect accumulating regions H. The surrounding regions under facets become low defect density single crystal regions Z.

Such a process forms orientation inversion regions J on masks M as defect accumulating regions H. On-mask formation of the orientation inversion regions J requires stable occurrence of the polarity inversion beaks Q midway on all the facets, for example {11-22} planes. Without stable happening of the beaks Q, defect accumulating regions H on masks do not become polarity inversion regions J. Without polarity inversion regions J, dislocations are not fully pulled into the defect accumulating regions H on masks. Non-existence of the polarity inversion regions J allows dislocations once gathered to escape from the bundles 11 below the bottoms of facets as show in FIG. 3(2). Without the polarity inversion regions J, the surroundings do not become low defect density single crystals.

Blunt vapor phase growth on masked undersubstrate cannot necessarily make inversion regions J on masks. It is not easy to stably produce polarity inversion regions Q upon slanting facets F rising from the verges of masks. Nobody has reported the conditions of making polarity inversion crystals on determined positions of growing GaN crystals. Furthermore nobody has clarified the conditions of yielding polarity inversion crystals on growing any kinds of crystals throughout the history of crystal growth.

The present invention aims at reducing dislocations by facet growth. Thus the present invention can be called a “facet growth method”. This invention is clearly different from the ELO (Epitaxial Lateral Overgrowth) method which decreases dislocations by making use of masks. The facet growth on which the present invention relies distinctly differs from the ELO. Both methods may be confused because of a common point of making use of masks for decreasing dislocations. Differences (a)-(c) are now clarified for avoiding confusion of the facet growth with the ELO.

Difference (a): Both methods are different with regard to existence or non-existence of the polarity inversion regions on masked parts. The ELO allows GaN crystals generated on exposed parts to overstep with maintaining the original orientation on masked parts. The orientation on the coated parts is the same as the orientation on the exposed parts in the ELO. In the ELO, a GaN crystal having, for example, a {11-22} facet on an exposed part will directly overstep onto a mask with keeping the same {11-22} facet. No orientation (polarity) inversion occurs at the verges of mask in the ELO. In the facet growth, GaN crystals produced on expose parts do not directly overstep on masks. Polarity (orientation) inversion regions Q happen at midway points on facets separating from masks at an early step. The polarity inversion regions J happen discontinuously from the mask. The facet growth has polarity inversion regions J on masks. The ELO has no polarity inversion regions J.

Difference (b): The direction of crystal growth for reducing dislocations is horizontal directions in the ELO. The ELO reduces dislocations by turning the growth direction from the initial vertical upward direction to horizontal directions at edges of masks. The direction of crystal growth in the facet growth is a vertical direction. The vertical growth has a function of gathering dislocations into the defect accumulating regions H and decreasing dislocation density in the surrounding regions. The facet growth and the ELO differ in the directions of crystal growth.

Difference (c): The ELO makes low density good quality GaN crystals on masks. High dislocation density poor quality GaN crystals are made on exposed parts in the ELO. On-mask crystals are good and off-mask crystals are poor in the ELO. On the contrary, the facet growth makes low dislocation density good GaN crystals on exposed parts and yields high dislocation density poor GaN crystals on masks. On-mask crystals are bad and off-mask crystals are good in the facet growth. The ELO and the facet growth are entirely contradictory with regard to whether low defect density GaN crystals and high defect density GaN crystals are made on exposed parts or coated parts.

### OBJECTS AND SUMMARY OF THE PRESENT INVENTION

This invention proposes a facet growth method of growing GaN crystals on an undersubstrate by depositing epitaxial growth-inhibiting masks partially on the undersubstrate, preparing a mixture of exposed parts and masked parts on the undersubstrate, growing GaN crystals on the partially coated undersubstrate in vapor phase, making polarity inversion regions J on the masks and growing a thick GaN crystal on the polarity inversion region-made undersubstrate in the facet growth condition till the end. The conventional GaN vapor phase growth contains two steps of buffer layer formation and epitaxial growth. This invention adds a step of inversion region formation. This invention includes three steps of buffer layer formation, inversion region formation and epitaxial growth.

The undersubstrate is a sapphire (Al₂O₃) (0001) single crystal wafer, a silicon (Si) (111) single crystal wafer, a silicon carbide (SiC) (0001) single crystal wafer, a GaN single crystal wafer, or GaAs (111) single crystal wafer. A GaN/sapphire wafer which is made by coating a sapphire wafer with a thin GaN film is called a “template”. The GaN/sapphire template can be also an undersubstrate.

A mask pattern is deposited on the undersubstrate. The materials of the mask are silicon dioxide (SiO₂), platinum (Pt), tungsten (W), silicon oxide nitride (SiON), silicon nitride (SiN), and so on. There is no problem using other materials capable of having thermochemical stability under the conditions of vapor phase growth and having the function of preventing GaN from epitaxially growing thereupon. The thickness of the mask is 30 nm to 300 nm. A mask pattern should be composed of regularly distributing masks. For example, one available mask pattern is a dot-type mask pattern (M2) which aligns many isolated mask dots in regular repetitions at a definite pitch. The dot-type mask pattern is now called a “dotmask” (M2) for short. Another available mask pattern is a stripe-type mask pattern (M1) which aligns parallel mask stripes at a definite pitch. The stripe-type mask pattern is called a “stripemask” (M1).

Parts coated with masks are named “covered parts” or “masked parts”. Other parts not coated with masks are named “exposed parts”, since the undersubstrate is exposed at the parts. In any of the facet growth masks, exposed parts are wider than the covered parts. The exposed parts can be true exposed parts without any mask. But the exposed parts otherwise can be coated with a fine ELO mask or a fine HELO mask having a several micrometer width and a several micrometer pitch. The ELO mask is far smaller than the facet growth masks in width and pitch. The ELO mask has a wider continual covered part than exposed parts. The narrow exposed parts in the ELO mask are called “windows”. On the ELO mask-formed exposed parts, GaN crystals happen on windows and overstep on masks in horizontal directions continually. The polarity inversion does not occur. The same orientation is always kept on the exposed parts. Dislocations are slightly reduced by the function of the ELO or HELO mask at an initial stage. The orientation and polarity are maintained on the ELO mask-formed exposed parts. Thus in spite of the existence of the ELO mask, the parts are still called “exposed parts”.

A GaN buffer layer with a thickness of 30 nm to 200 nm is formed on the mask-formed undersubstrate by growing GaN in vapor phase at a low temperature. The buffer layer formation temperature is denoted by Tb. The buffer layer formation temperature is a low temperature of Tb=400° C. to 600° C. The buffer layer has a function of alleviating the stress caused between the undersubstrate and GaN layers. The buffer formation growth is the zero-th growth.

The gist of the present invention is the first growth for making inversion regions J following the zero-th growth. The purpose of the first growth is to produce inversion regions J on masks. In the first growth, GaN crystals happen and grow on exposed parts, and masks prevent GaN from growing thereon. GaN crystals on exposed parts make inclining facets F at portions in contact with brims of masks. In the optimum case, small beaks Q happen midway on facets F which start from the verges of masks and arrive at C-plane surfaces of growing GaN crystals on exposed parts. The beaks have orientation inverting by 180 degrees to the surrounding crystals. Progress of GaN crystal growth dilates and prolong the beaks Q on the facets, maintaining the inversion of orientation. Tips of a pair of beaks Q and Q come into contact with each other. The beaks Q and Q are unified into one above masks. GaN is epitaxially piled on also the unified beaks Q as seeds. GaN crystals are grown also above the masked parts with delay. The GaN crystals growing on the beaks Q have orientation and polarity by 180 degrees inverting to the surrounding GaN crystals. Then the regions are named “orientation inversion regions” J. In the orientation inversion regions J, polarity, c-axis and other axes are inversion. “Polarity inversion regions”, “c-axis 180 degree inversion regions”, “inversion regions” and “orientation inversion regions” are synonyms. The inversion region J upward grows on the mask with maintaining a definite horizontal section of an area slightly smaller than the mask. The polarity inversion regions J as defect accumulating regions H attract, gather and accommodate dislocations.

Since the on-mask regions assemble dislocations, the regions on the masks are called “defect accumulating regions” H. The defect accumulating regions H have four different types; A, P, J and O. One type is a c-axis inclining single crystal (A). Another type is a polycrystal (P). Another type is a c-axis inversion region J. Sometimes any defect accumulating regions are not produced (O) on masks.

Among the four types of A, P, J and O, the present invention aims at making the inversion regions J on masks as defect accumulating regions H. The on-mask defect accumulating regions H have a function of attracting dislocations out of the neighboring GaN crystals grown below facets and arresting the dislocations in the defect accumulating regions H. The neighboring GaN crystals from which dislocations are swept become low defect density. The dislocation attracting function is the strongest in the inversion region J. Three other types of H have a weaker function of gathering/arresting dislocations than the inversion region J. The inversion region J is the best for defect accumulating regions H.

Searching the conditions of making inversion regions on masks with certainty, the present invention succeeds in producing inversion regions J on masks by facet growth without fail.

Cathode luminescence is able to examine the occurrence or non-occurrence of orientation inversion regions on masks. A fluorescence microscope can inspect whether orientation inversion regions J happen on masks. GaN crystals are transparent for visible light. Human eye sight cannot examine the structure on the masks.

For forming the c-axis inversion regions J as defect accumulating regions H, the inventors have found the fact that the conditions of forming defect accumulating regions on masks at an initial stage are important. If the initial conditions of forming the on-mask defect accumulating regions H are not well adjusted, the on-mask defect accumulating regions H do not become polarity inversion regions J but become polycrystals (P) or c-axis inclining single crystals (A). Otherwise defect accumulating regions do not occur on masks and the on-mask regions (O) only become shallow cavities. The polycrystal (P) or c-axis inclining single crystal (A) has an insufficient power for attracting dislocations from the surrounding regions, annihilating dislocations and accommodating dislocations without release. The simple cavities (O) without defect accumulating regions H on masks have no power of attracting dislocations. The best of the defect accumulating regions H is the inversion region J. It is ardently desired to convert the on-mask regions to the polarity inversion regions J.

Among the aforementioned processes, steps (3), (4), (5) and (6) correspond to the initial stage of forming polarity inversion beaks Q. Occurrence of the polarity inversion beaks Q is very important. The present invention clarifies the conditions of making polarity inversion beaks Q and the following polarity inversion regions J. It should be clarified what range of temperatures, what range of growing speeds, what kind of undersubstrates and what kind of mask materials are suitable for making polarity inversion regions on masks. The aim of the present invention is, as it were, to answer the questions.

The growth which produces the inversion beaks Q and the polarity inversion regions J is called a “first growth”. The growth temperature which makes the beaks Q and the inversion regions J is called a “first growth temperature” Tj(° C.). When tiny beaks Q and inversion regions J once happen, a thick GaN crystal is grown on conventional facet growth conditions. The time required for making the inversion regions J, which depends upon the growing speed, is a short time of about 0.25 hour to 2 hours.

Plenty of experiments teach the inventors that first growth temperatures ranging Tj=900° C. to 990° C. enable inversion regions J to happen on all or almost of the masks and allow the neighboring regions Z to become low dislocation density. The temperature range Tj=900-990° C. had been deemed to be too low and unsuitable for vapor phase epitaxy of CaN crystal. In general, it has been believed that higher temperature growth is favorable for making high quality GaN crystals. GaN epitaxial growth in vapor phase had been done at a high temperature more than 1000° C. The inventors have found that low temperatures of 900° C. to 990° C. are pertinent for making inversion regions J on masks without fail at an early stage. The pertinent range of the first temperature of 900° C. to 990° C. is less than the conventional epitaxial growth temperature (higher than 1000° C.).

The inventors have discovered that a more restricted range of the first growth temperature Tj=920° C.-960° C. enbles a wide scope of different growing speeds Vj to produce inversion regions J on allover masks M. The range of Tj=920° C.-960° C. as first growing temperatures Tj is more favorable for making GaN substrate crystals in industrial scale, since the temperature range allows the facet growth to yield inversion regions J and low defect density single crystal regions Z with high stability.

The inventors have carried out many systematical experiments of growing GaN crystals within and beyond the above temperature range for searching preferable conditions of making inversion beaks on facets. FIG. 11 is a graph showing results of experiments of the first growth as a function of temperature T (K) and growing speed Vj(μm/h). The abscissa is 1000/T. The ordinate is growing speed Vj(μm/h). Black rounds signify very good sets of a growth temperature T and a growing speed Vj which succeed in making continual inversion regions J. 13 black rounds appear in the graph of FIG. 11. The leftest black round has 1000/T=0.792. Then T=1263K, Tj=990° C. The rightest black round denotes 1000/T=0.853. Thus T=1172K. Tj=899° C. All the 13 black rounds are included in a range of temperatures between 900° C. and 990° C.

Blank rounds signify allowable sets of T and Vj which make intermittent inversion regions J. Some blank rounds are included within the temperature range Tj=900° C.-990° C. Some blank rounds (rightest) exist at lower temperatures under 900° C. Other blank rounds (leftest) exist at higher temperatures over 990° C. All the blank rounds are sandwiched by two straight lines. Then the scope of the allowable T and Vj can be expressed by inequalities.

Blank triangle denote rejected sets of T and Vj which cannot make inversion regions J. All the blank triangles are out of the two straight lines. The condition of the first growth for yielding inversion regions J depends upon a growing speed Vj (μm/h) as a function of the temperature Tj. The range of preferable growing speeds depends upon the first growth temperature Tj. The preferable first growth temperature Tj (° C.) and the favorable growing speed Vj (μm/h) are mutually related with each other. The inventors have found that the condition of making inversion regions J on masks is a scope of Vj and Tj which is expressed by the following inequalities.
−439×{1000/{Tj+273.15)}+387<Vj<−736×{1000/(Tj+273.15)}+737.

The condition defined by the above inequalities is favorable for yielding inversion beaks Q and inversion regions J. The above inequalities include temperature in Celsius (° C.). Tj(° C.)+273.15 is an absolute temperature (Kelvin) T(K). T(K)=Tj+273.15. An equivalent expression in term of absolute temperature T(K) is given by,
−4.39×10⁵/T+3.87×10²<Vj<−7.36×10⁵/T+7.37×10².

The inequalities are obtained by the two straight lines which are drawn for discriminating the allowable T and Vj sets (blank rounds) from the rejected T and Vj sets (blank triangles) in FIG. 11. The upper line is denoted by Vj<−7.36×10⁵/T+7.37×10². The lower line is denoted by Vj=−4.39×10⁵/T+3.87×10². An equivalent expression of the favorable sets of T(K) and Vj(μm/h) is given by
a₁/T+b₁<Vj<a₂/T+b₂,
where a₁=−4.39×10⁵ (Kμm/h), b₁=3.87×10² (μm/h), a₂=−7.36×10⁵ (Kμm/h) and b₂=7.37×10² (μm/h). The inequalities include favorable sets (black rounds) and allowable sets (blank rounds) of T and Vj in FIG. 11.

The inequalities signify the growing condition corresponding to the scope of growing speeds Vj and temperatures T sandwiched by two solid lines drawn in FIG. 11. Even if the first growing temperature Tj exceeds the scope between 900° C. and 990° C., the growing speed Vj within the range denoted by the inequalities can make inversion regions J on masks M. The inventors have discovered for the first time the fact that the growing speed and the temperature are mutually related with each other and cooperated in facilitating the occurrence of inversion regions J on masks M.

It is strongly desired that the first growth should be carried out at a temperature and a growing speed satisfying the above inequalities for making polarity inversion regions J on overall masks. Thereby complete formation of the on-mask inversion regions J should ensure the surrounding crystals to be low dislocation density. However even when inversion regions J are not overall formed but are intermittently formed on most of the masks M, the following facet growth can produce useful GaN crystals. In the case, since most of the masks have inversion regions J, the inversion regions J attract, arrest and annihilate dislocations and the surrounding crystals become low defect density.

Pertinent ratios P_{NH3}/P_{HCl} of ammonia partial pressure P_{NH3} to hydrochloride partial pressure P_{HCl} are P_{NH3}/P_{HCl}=3 to 50 in the first growth. The ammonia partial pressure P_{NH3} should be equal to or higher than 5 kPa but equal to or lower than 30 kPa in the first growth.
0.05 atm (5 kPa)≦P_{NH3}≦0.3 atm (30 kPa)

The time of the first growth is 0.25 hour to 2 hours. At the end of the first growth, orientation inversion regions J have been made on masks as defect accumulating regions H. Low defect density single crystal regions Z are produced upon exposed parts. Sometimes C-plane growth regions Y are made at middles of the exposed parts. Sometimes no C-plane growth regions Y happen.

Following the first growth, epitaxial growth for making a thick GaN crystal is done. The growth for producing a thick GaN crystal is called a “second growth”. The time of the second growth, which depends upon the thickness of an object GaN crystal, is several tens of hours, several hundreds of hours, or several thousands of hours. The temperature of the second epitaxial growth is named a “second growth temperature” Te. The epitaxial growth temperature Te should be higher than 990° C. (Te>990° C.). An appropriate second temperature range is Te=1000° C. to 1200° C.

High quality GaN substrates of low defect density are ardently desired. The present invention clarifies the conditions of producing inversion regions J on masks as defect accumulating regions H at an initial stage in the facet growth method composed of the steps of implanting masks M on an undersubstrate U, growing GaN in vapor phase, inducing facets on a growing GaN crystal, preparing defect accumulating regions H on the masks at pits or grooves, maintaining facet pits or facet grooves, gathering dislocations into the facet pits or the grooves and decreasing dislocation density in the surrounding regions. The present invention demonstrates requisite conditions of preparing inversion regions J on masks M. The present invention gives high quality GaN substrate crystals by adjusting the first growth temperature and the first growing speed, enabling masks to make definite inversion regions J and allowing the inversion regions J to decrease dislocations in the surrounding single crystal regions Z and Y.

### BRIEF DESCRIPTION OF THE DRAWINGS

FIG. 1(a) is a perspective view of a facet pit appearing on a growing surface at a starting stage of growth for demonstrating the facet growth method proposed by (2) Japanese Patent Laying Open No. 2001-102307 which makes hexagonal facet pits on a growing surface, grows GaN without burying the facet pits, concentrates dislocations at boundaries of the facets and gathers dislocations at bottoms of the facet pits.

FIG. 1(b) is a perspective view of a facet pit appearing on a growing surface at a later stage of growth for demonstrating the facet growth method proposed by (2) Japanese Patent Laying Open No. 2001-102307 which makes hexagonal facet pits on a growing surface, grows GaN without burying facet pits, concentrates dislocations at boundaries of the facets and gathers dislocations at bottoms of the facet pits.

FIG. 2 is a plan view of a facet pit appearing on a growing surface for demonstrating the facet growth method proposed by (2) Japanese Patent Laying Open No. 2001-102307 which makes hexagonal facet pits on a growing surface, grows GaN without burying facet pits, concentrates dislocations at boundaries of the facets and gathers dislocations at bottoms of the facet pits.

FIG. 3(1) is a sectional view of a facet pit appearing on a growing surface for demonstrating the facet growth method proposed by (2) Japanese Patent Laying Open No. 2001-102307 which makes hexagonal facet pits on a growing surface, grows GaN without burying facet pits, concentrates dislocations at boundaries of the facets, gathers dislocations at bottoms of the facet pits and makes a dislocation bundle.

FIG. 3(2) shows a sectional view of a facet pit with a hazy dispersion of dislocations escaping from the pit.

FIG. 4(1) is a sectional view of a pit or V-groove at an early stage for demonstrating the mask-facet growth method proposed by (3) Japanese Patent Laying Open No. 2003-165799 and (4) Japanese Patent Laying Open No. 2003-183100 which make dislocation-attractive defect accumulating regions (H) on masked parts, make low defect density single crystal regions (Z) under facets, produce C-plane growth regions (Y) under C-plane surface and maintain dislocations in the defect accumulating regions (H).

FIG. 4(2) shows a sectional view of the pit or V-grooves at a later stage for showing dislocations being arrested in the defect accumulating regions (H) without being dispersed till the end of the growth.

FIG. 5(1) is a section of an undersubstrate U and a mask M formed on the undersubstrate U at a start of the facet growth method.

FIG. 5(2) is a section of the undersubstrate, the mask and GaN crystals at a later stage for showing the masked parts prohibited from growth, slanting facets starting from ends of the mask and rising to the C-plane surface.

FIG. 5(3) is a section of the undersubstrate, the mask and GaN crystals at a further later stage for showing the occurrence of a defect accumulating region (H) on the masked parts and appearance of two step facets in the pit or the valley.

FIG. 6(1) is a perspective view of a prism-roofed GaN crystal produced by a facet growth method that forms mask stripes on an undersubstrate, grows GaN in vapor phase, produces facet valleys and makes defect accumulating regions on the stripe-covered parts.

FIG. 6(2) is a perspective view of a pit-roofed GaN crystal produced by a facet growth method that forms mask dots on an undersubstrate, grows GaN in vapor phase, produces facet pits and makes defect accumulating regions on the dot-covered parts.

FIG. 7(1) is a section of an undersubstrate and a mask.

FIG. 7(2) is a section of the undersubstrate, the mask, GaN crystals grown on exposed parts, and facets starting from ends of the mask.

FIG. 7(3) is a sectional view for showing beaks appearing on slants of the facets.

FIG. 7(4) is a sectional view for showing the beaks meeting together above the mask and being unified with each other.

FIG. 7(5) is a sectional view for showing GaN crystals growing on the unified beaks with the same orientation as the beaks.

FIG. 8(1) is a plan view of an undersubstrate and linear parallel mask stripes formed at a pitch p on the undersubstrate.

FIG. 8(2) is a CL (cathode luminescence) image of a facet-grown, sliced and polished GaN crystal having parallel low dislocation single crystal regions (Z), C-plane growth regions (Y) and defect accumulating regions (H).

FIG. 9(1) is a section of an undersubstrate.

FIG. 9(2) is a section of the undersubstrate and mask stripes in the strip-mask facet growth.

FIG. 9(3) is a section of the undersubstrate, the mask stripes, and a thick grown GaN crystal on the masked undersubstrate with defect accumulating regions (H) on the mask stripes, low defect single crystal regions (Z) below facets on exposed parts and C-growth regions below C-plane surfaces on the expose parts.

FIG. 9(4) is a CL image of a flat HZYZHZYZH structured GaN crystal produced by eliminating the undersubstrate from the GaN crystal, grinding the separated GaN crystal and polishing the GaN crystal.

FIG. 9(5) is a CL image of a flat HZHZH structured GaN crystal without C-plane growth regions.

FIG. 10(1) is a plan view of an undersubstrate and isolated mask dots formed at a pitch p with six-fold symmetry on the undersubstrate in the dot-mask facet growth.

FIG. 10(2) is a CL image of a flat HZY hexagonal symmetric GaN crystal produced by eliminating the undersubstrate from the GaN crystal, grinding the separated GaN crystal and polishing the GaN crystal.

FIG. 11 is a graph showing the occurrence of inversion regions J which depend upon the temperature and the growing speed. The abscissa is 1000/T(K⁻¹), where T is an absolute temperature (273+° C.) of the first growth. The ordinate is growing speeds (μm/h). In the graph, black rounds denote that inversion regions J occur upon all the masks M at the temperature and the growing speed. Blank rounds mean that inversion regions happen on most masks at the temperature and the speed. Blank triangles denote that that inversion regions J occur on few masks. Results of Embodiments 1-5 are shown in the graph. Black rounds and blank rounds mean allowable conditions of temperatures and growing speeds for making inversion regions J on masks. Blank triangles mean rejected conditions of temperatures and growing speeds for making inversion regions J on masks. Upper and lower solid lines are drawn between rejected triangles and allowable rounds. Temperatures and growing speeds in the scope sandwiched between the upper line and the lower line promote the occurrence of inversion regions J on masks. The upper line is denoted by V=−7.36×10⁵/T+7.37×10², where V is a growing speed (μm/h) and T is an absolute temperature (K) of the first growth temperature. The lower line is denoted by V=−4.39×10⁵/T+3.87×10². Temperatures and growing speeds out of the scope sandwiched between the upper line and lower line prevent inversion regions J from occurring on masks.

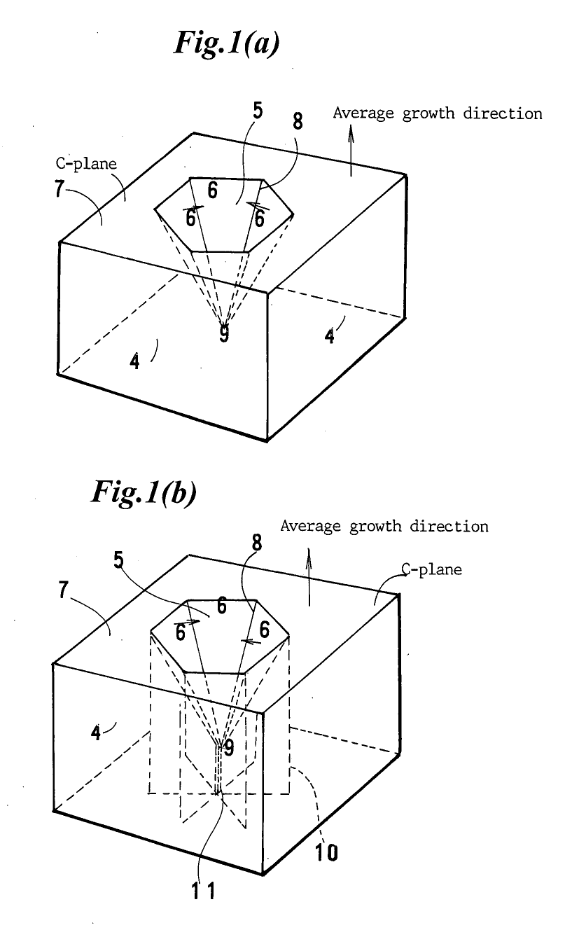

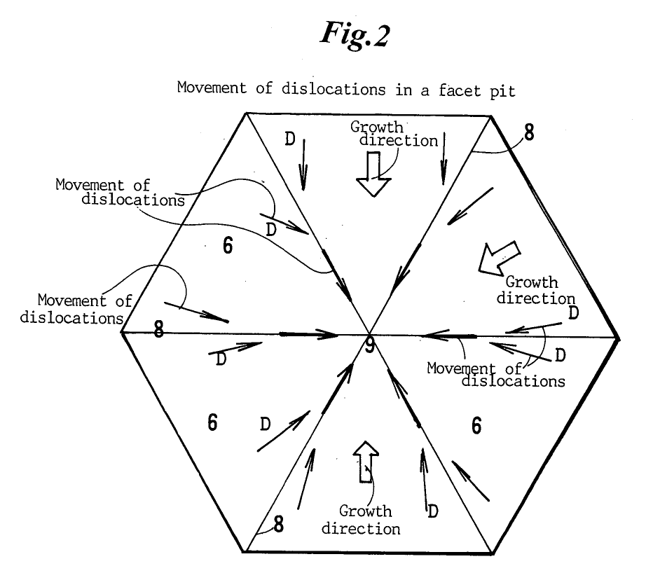

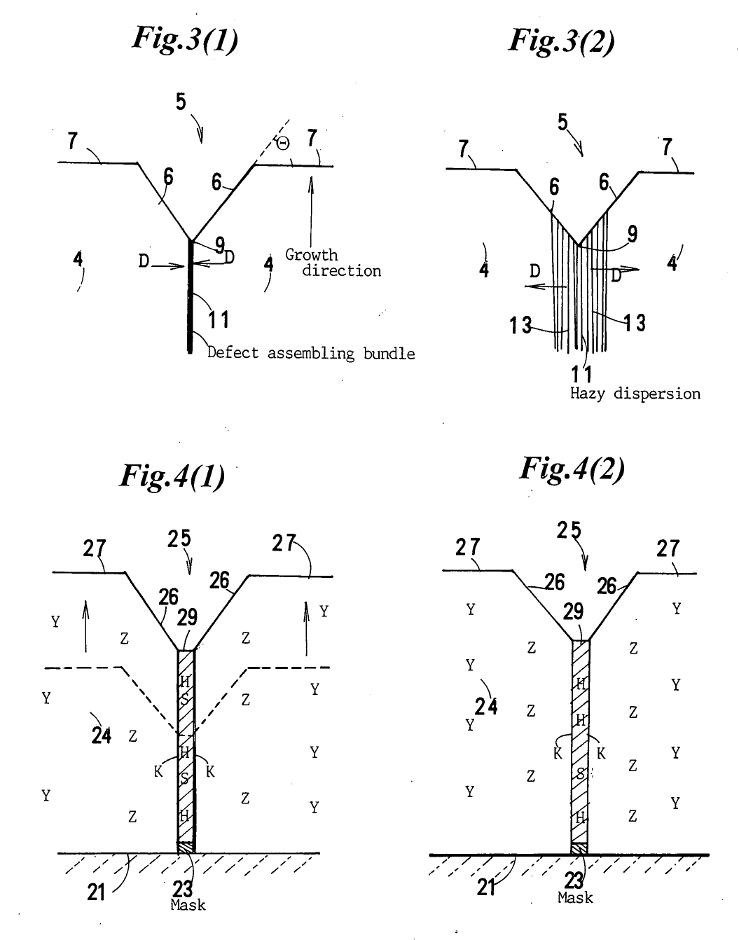

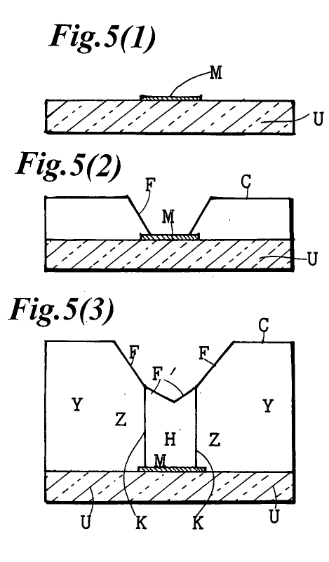

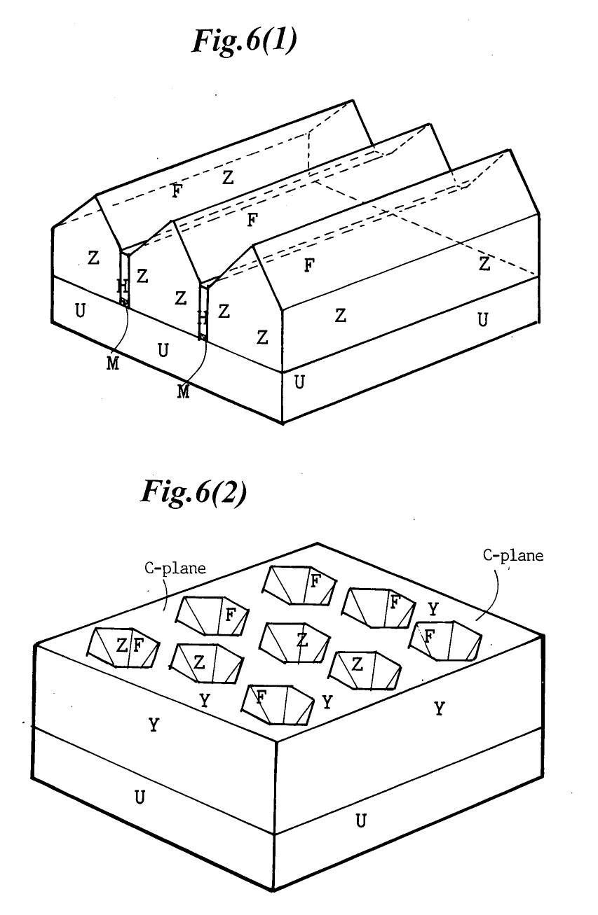

### DETAILED DESCRIPTION OF PREFERRED EMBODIMENTS

A hydride vapor phase epitaxy (HVPE) method, metallorganic chemical vapor deposition (MOCVD) method, metallorganic chloride (MOC) method and sublimation method are known as a growing method of gallium nitride crystals in vapor phase. The HVPE has an advantage of high speed growth. Recent development enables even the MOCVD method to grow gallium nitride at a high speed more than 50 μm/h. The MOCVD or the MOC may grow gallium nitride in a similar manner explained hereafter. Among the known growth methods, the HVPE is superior in the growing speed, material yield and cost at present. Thus this invention searches appropriate conditions of making orientation inversion regions J only in the HVPE method.

A flux method makes GaN crystals in liquid phase. More than 40 μm/h growing speed in a flux method has recently been reported. But the growing speed in the flux method is far slower than the reported data. Further, a liquid phase method grows GaN crystals from a material liquid at thermal equilibrium. The principle and condition of the growth of the liquid phase method are far different from the vapor phase methods. Thus liquid phase growth methods are out of the reach of the present invention.

GaN crystals grown by the HVPE method are described hereafter. The present invention uses, for example, a horizontally long hot-wall HVPE reaction furnace. The horizontal-type furnace has a plurality of horizontally-divided heaters. The heaters can form arbitrary temperature distribution in the horizontal direction in the HVPE furnace. The furnace has a Ga-metal boat with metal gallium at an upstream part and a susceptor for supporting specimens at a downstream part. In a usual case, the crystal growth is done at the atmospheric pressure (1 atm=100 kPa=760 Torr) in the HVPE furnace. The Ga-boat is heated up to 800° C. Ga metal is molten into a Ga liquid. The Ga-metal boat contains a Ga-melt at 800° C. Gas inlet pipes are furnished at an upstream part. A gas inlet pipe introduces H₂+HCl (hydrogen+hydrochloride) gas in the furnace to the hot Ga-melt. Reaction of HCl with Ga-melt synthesizes gallium chloride (GaCl). GaCl is gaseous. Gaseous GaCl drifts downward toward the susceptor and specimens. H₂+NH₃ (hydrogen+ammonia) gas is introduced via another gas inlet pipe of the furnace to the vicinity of the susceptor/specimens. Reaction of GaCl with NH₃ makes GaN. Synthesized GaN is piled upon the specimens on the susceptor. GaN is grown on the specimens.

The present invention forms mask patterns on an undersubstrate. The mask patterns should be made of a material which prevents GaN from epitaxially grow. The mask can be made of SiO₂ (silicon dioxide), SiON (silicon oxide nitride), SiN (silicon nitride), Pt (platinum), W (tungsten) and so on.

Masks become seeds of defect accumulating regions H. Orientation of growing GaN crystals is determined by the orientation of the undersubstrate. Mask extending directions determine the orientation of the facets generated along the masks. The extension direction of masks should be determined to have a definite relation with the orientation of the undersubstrate.

### Embodiment 1

### Dependence of Inversion Regions J Upon First Temperature Tj

Embodiment 1 studies how the occurrence of inversion regions J depends upon the first temperature Tj, which is the temperature at the step of making inversion regions J on masks.

[1. Undersubstrates (U)]

2 inch diameter sapphire single crystal wafers (U1), 2-inch diameter GaAs single crystal wafers (U2) and 2-inch GaN/sapphire wafers (U3) which are 1.5 μm thick GaN layer coated sapphire wafers are prepared. The sapphire wafers (U1) are C-plane ((0001) plane) surface wafers. The GaAs wafers (U2) are GaAs(111)A-plane (Ga-plane) wafers. The GaN/sapphire wafers have C-plane sapphire wafers and 1.5 μm GaN thin layers deposited thereon. GaN/sapphire wafers are sometimes called “templates”.

[2. Mask Patterns (M)]

Masks should have a property of inhibiting GaN from epitaxial growing. 0.1 μm thick SiO₂ layers are deposited on three kinds of undersubstrates U1, U2 and U3. Photolithography and etching pattern the SiO₂ layers into definite masks on the undersubstrates. The masks have two patterns. One is a stripemask (M1) having plenty of parallel mask stripes aligning at a definite pitch. The other is a dotmask (M2) having isolated mask dots aligning two dimensionally regularly at a definite pitch.

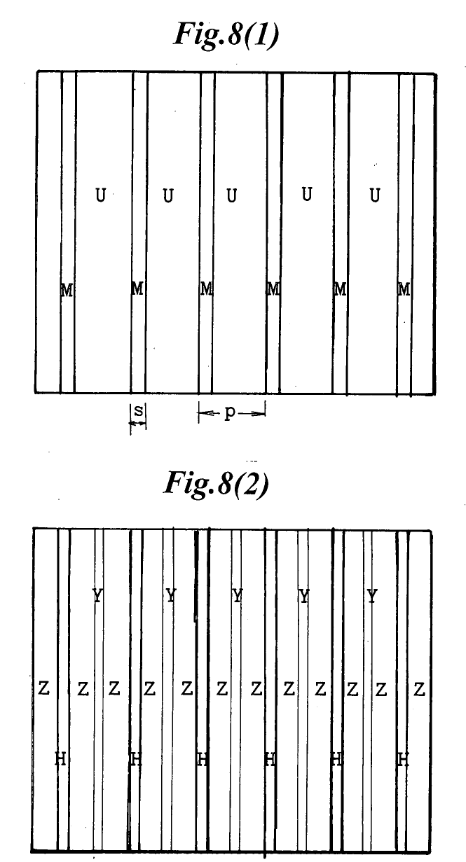

(M1: Stripemask Pattern: FIG. 8(1))

FIG. 8(1) exhibits a stripemask pattern (M1) consisting of parallel stripes formed on an undersubstrate (U). The extension direction of mask stripes is parallel with a GaN <1-100> direction. The mask is formed before the GaN epitaxial growth. There is no GaN layer on an undersubstrate when the mask is formed. There is a definite relation between the undersubstrate orientation and the GaN orientation. The GaN orientation can be known from the undersubstrate orientation. When a GaN layer is grown on a sapphire (0001) wafer, orientation of GaN is twisted by 90 degrees around the c-axis. When a GaN layer is grown on a GaAs(111) wafer, attention should be paid to the relation between the GaAs and GaN orientations, since hexagonal system GaN is grown on three-fold symmetric GaAs(111) surface. When a GaN layer is grown on a GaN (0001) wafer, the orientation of GaN layer is identical to the orientation of the GaN wafer. Mask patterns parallel to GaN<1-100> direction can be formed on an undersubstrate by taking account of the relation to GaN/undersubstrate orientations.

Stripemasks having stripes parallel to GaN<1-100> can be prepared by the following guidelines. In the case of a GaN/sapphire template undersubstrate (U3), mask stripes should be determined to be parallel to a GaN<1-100> direction. In the case of a GaAs(111)A-plane undersubstrate (U2), mask stripes should be determined to be parallel to a GaAs<11-2> direction. In the case of a sapphire (0001) undersubstrate (U1), mask stripes should be determined to be parallel to a sapphire <11-20> direction.

The stripemask pattern has covering stripes having a width s=30 μm and repeating at a pitch p=300 μm. There are parallel undersubstrate-exposed parts with a width e=270 μm. Masked parts are called covered parts. The sum of an exposed part width e and a stripe width s is equal to a pitch p. Namely p=e+s. A pitch is a distance between the center of a covered part and the center of a neighboring covered part. In the example, the ratio of exposed parts to covered parts is 9:1. Exposed parts are far wider than covered parts.

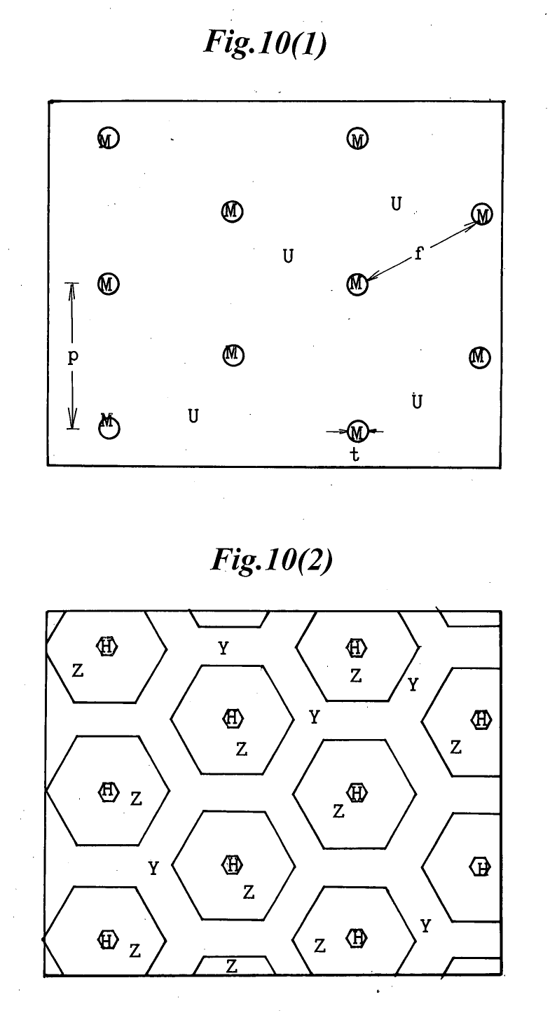

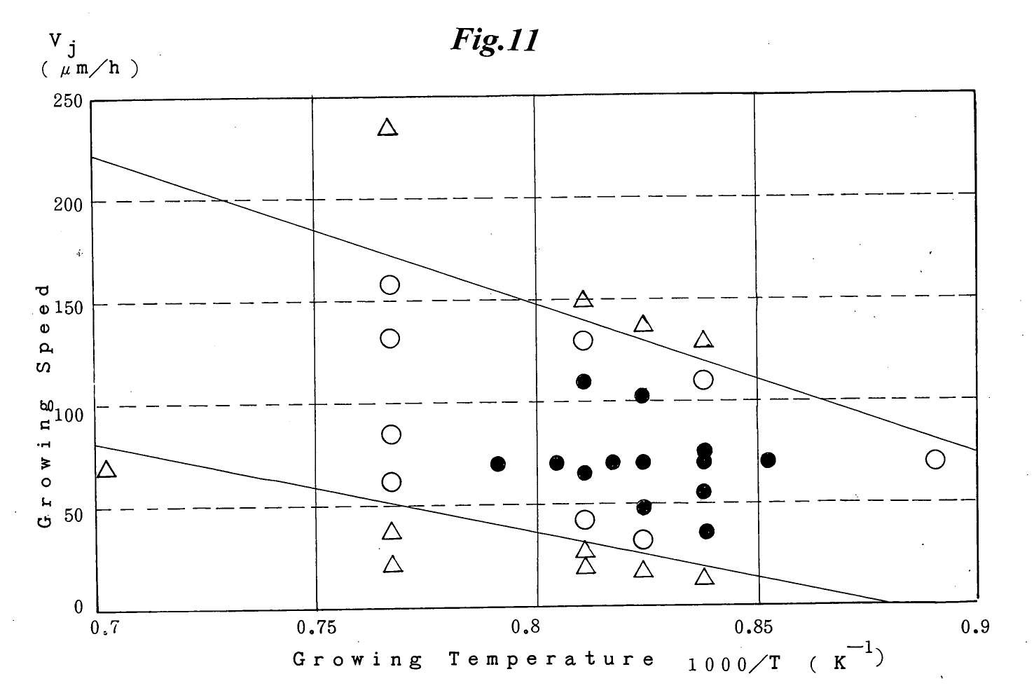

(M2: Dotmask Pattern: FIG. 10(1))

FIG. 10(1) shows a dotmask pattern having a plurality of parallel trains of isolated round dots aligning with a half pitch discrepancy. Diameter of a dot is denoted by t. Pitch of repetitions is denoted by p. Distance between neighboring dots is denoted by f. f+t=p. The pattern consists of dots laid on the corners of equivalent regular triangles repeating in three directions without gap. The pattern has six fold rotation symmetry as shown in FIG. 10(1). The directions of the dot trains are predetermined to be parallel to GaN<1-100> directions. As mentioned before, although mask formation precedes GaN growth, it is possible to determine the stripe extending direction parallel to an afterward grown GaN<1-100> direction. In the case of a sapphire undersubstrate (U1), trains of dots should be formed to be parallel to sapphire <11-20> directions. In the case of a GaAs(111) undersubstrate (U2), trains of dots should be formed to be parallel to GaAs <11-2> directions.

In the example, the dot is a round. The diameter of a dot is t=50 μm. The pitch is p=300 μm. The distance between neighboring dots is f=250 μm. Unit regular triangle having dots at corners has an area of 38971 μm². Area of a dot is 1963 μm². The area ratio of the exposed parts to covered parts is 19:1. Three kinds of undersubstrate U1, U2 and U3 and two kinds of mask M1 and M2 make six kinds of masked undersubstrate M1U1, M1U2, M1U3, M2U1, M2U2 and M2U3.

[3. Inversion Region Generating Temperature Tj]

The growing temperature for producing the orientation inversion regions on masks is denoted by “Tj”. This is otherwise called a “first growth temperature ” Tj. Embodiment 1 tries to make the on-mask inversion regions at seven different temperatures Tj1 to Tj7. Tj1=850, Tj2=900, Tj3=920, Tj4=950, Tj5=970, Tj6=990 and Tj7=1150. Six kinds of masked undersubstrates and seven different temperatures produce 42 different specimens.

[4. Other Conditions for Growth (Buffer Layer Formation)]

The masked undersubstrates (U1, U2, U3; M1, M2) are inputted into a HVPE furnace and are placed on a susceptor. The susceptor and specimens are heated to about 500. At an initial step, GaN buffer layers are grown upon the masked undersubstrates at a low temperature of about Tb=500 under ammonia partial pressure P_{NH3}=0.2 atm (20 kPa) and hydrochloride partial pressure P_{HCl}=2×10⁻³ atm (0.2 kPa). The time of forming the GaN buffer layers is 15 minutes. The thickness of the GaN buffer layers is about 60 nm.

Then each set of six kind susceptor/specimens is heated up to a predetermined first growth temperature of Tj1 to Tj7. The first growth produces orientation inversion regions on the masked parts and epitaxial layers on exposed parts. Ammonia partial pressure is P_{NH3}=0.2 atm (20 kPa). Hydrochloride partial pressure is P_{HCl}=2×10⁻² atm (2 kPa). The growing time is 60 minutes. An average thickness of the grown crystals is about 70 μm. The thickness is independent of the kinds of undersubstrates U1, U2 and U3. The growing speed is Vj=70 μm/h.

[5. Growth for Producing Inversion Regions J]

Experiments give knowledge of the situations of crystal growth of generating the 180 degree c-axis inversion regions as follows.

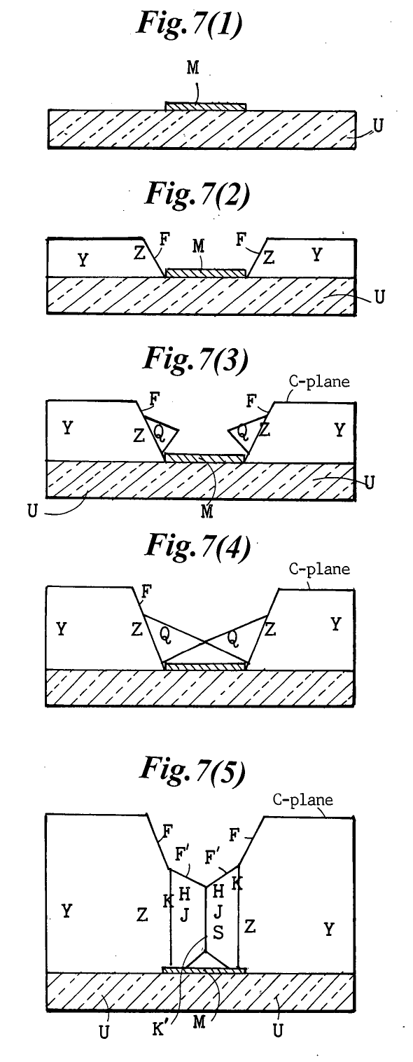

A series of occurrence of an inversion region J is clarified by referring to FIG. 7(1)-FIG. 7(5). FIG. (1) denotes a part of an undersubstrate U partial coated with a mask M. Although plenty of mask dots or stripes are formed on an undersubstrate, FIG. 7(1)-FIG. 7(5) denote only a dot or a stripe for short. The sectional view is similar for both a dotmask M2 and a stripemask M1. Here FIG. 7(1)-FIG. 7(5) mean a stripemasked specimen. The mask stripe M extends in the direction vertical to paper.

Then vapor phase GaN growth starts. GaN nuclei happen on exposed parts. No GaN nucleus appears on masks M at an initial stage. When a buffer layer is made, the height of the buffer layer is lower than that of the mask. As shown in FIG. 7(2), on-exposed-part GaN films grow thicker on all exposed parts without overlapping the masks. The masks have a strong function of suppressing GaN growth. The GaN films have flat surfaces and slants. A slant starts from a verge of the mask and arrives at a flat surface. During further growth, the slants rise and become facets with definite angels (FIG. 7(2)). Orientation of the facets depends upon the direction of the masks. For example, the facets F are {11-22} facets when the stripes of the mask are directed in GaN <1-100>. Masks are free from GaN grains. A pair of facets F and F confront each other across the mask M. Regions beneath the facets F are low defect density single crystal regions Z. Regions below the flat C-planes are C-plane growth regions Y. In FIG. 7(2), GaN crystals consist of Z and Y. Z and Y are GaN single crystals epitaxially grown on exposed parts.

A sign of generating of inversion regions J is an appearance of rugged protrusions midway on inclining facets F. The slanting protrusions are called “beaks” Q. Beaks Q and Q confront each other across the mask M. When no beak appears, no inversion regions J occur on masks. The beaks are polarity inversion crystals having a 180 degree inversion c-axis. Polarity means the direction of the c-axis. Polarity inversion means that the crystal has a 180 degree inversion c-axis in comparison with the surrounding crystals (Z and Y). The upper surface of the beaks Q inclines at 25 degrees to 35 degrees to the horizontal plane. The beaks are polarity inversion crystals having a c-axis by 180 degrees inverted to the neighboring crystals Z. Since the orientation of the beaks Q is inverse, the beaks Q can be seeds of the orientation inversion regions J. When the crystal growth proceeds, rugged beaks Q grow bigger and longer. Tips of beaks Q extend and come into contact with each other above the mask M as shown in FIG. 7(4). A pair of the beaks Q are unified and bridged across the mask. The beaks Q are not in contact with the mask M.

Following the unification of the beaks, GaN grows on the beaks Q as seeds. The GaN piling on the seeds has the same polarity as the beaks Q. Since the beaks are inversion crystals, the GaN grown on the beaks above the masks is a polarity inversion crystal. All GaN crystals grown on the beaks are orientation inversion crystals. Regions above masks are called “defect accumulating regions” H. In the case, the defect accumulating regions H are inversion regions J. GaN crystals which are taller than the inversion regions J are still grown on both exposed parts (FIG. 7(5)). Top flat surfaces are C-planes. Slants are facets F. Crystals grown on the exposed parts contain plenty of dislocations generated at the boundaries between the undersubstrate and the grown crystals. Dislocations extend upward, accompanying the GaN growth. The present invention grows GaN crystals by making facets and keeping facets. This is the facet growth method on which the present invention relies. GaN continues to grow without burying the facets. Crystals grow in the direction parallel to the normals standing on the facets. Accompanying crystal growth, dislocations extend in the same direction as the crystal growth. Dislocation extension is parallel to the growth direction. Then directions of dislocation extension are slantingly upward from the facets.

Dislocations prolong toward defect accumulating regions H on masks. When dislocations arrive at the defect accumulating region H, the dislocations are absorbed and arrested in the defect accumulating regions H. When the defect accumulating region H is an orientation inversion regions J, the crystal orientation is inverse in the defect accumulating region H. The boundary is an orientation transition plane, which firmly arrests dislocations and prohibits once-arrested dislocations from releasing. The once-arrested dislocations never return to the regions Z below the facets. Dislocations in the facet-below regions Z irreversibly decrease. Dislocation density is decreasing during the allover crystal growth in the facet-below regions Z. Thus the facet-below regions Z on exposed parts are called “low defect density single crystal regions” Z. The facet-below regions have plenty of dislocations generated at interfaces between the regions Z and the undersubstrate U at an initial stage. The following facet growth carries dislocations from the facet-below regions Z to the on-mask defect accumulating regions H. The facet-below regions Z become low dislocation density. The facet-below regions Z are single crystals determined by the orientation of the undersubstrate U. Then it is valid to name the facet-below regions as low defect density single crystal regions Z. The facet growth continues till the end of the growth. Expelling dislocations from Z continues till the end. The single crystal regions Z become lower and lower defect density. Sometimes C-plane growth regions Y remain till the end on exposed parts. The C-plane growth regions Y become low dislocation density because dislocations diffuse to neighboring facet-below regions Z due to dislocation density gradient.

The above is the best case. On the contrary sometimes no inversion regions J are generated on masks. It is supposed that occurrence or non-occurrence of the inversion regions J on masks would depend upon the temperature Tj, the gas flow, the undersubstrate U, the mask material and so on. Embodiment 1 examines the influence of the temperature Tj upon the on-mask inversion region formation on condition of Vj=70 μm/h, P_{NH3}=20 kPa and P_{HCl}=2 kPa.

[(1) In the Case of Tj1=850]

Undersubstrate: sapphire(0001) wafer (U1), GaAs(111) wafer (U2), GaN/sapphire template (U3).
Mask Pattern: Stripemask (M1), Dotmask (M2).
   Vj=70 μm/h, P_{NH3}=20 kPa, P_{HCl}=2 kPa.
   Result of Observation
M1: stripemask: Wavy orientation inversion regions J intermittently occur on most mask stripes.
M2: dotmask: Orientation inversion regions J occur on most mask dots.
   [(2) In the Case of Tj2=900]
Undersubstrate: sapphire(0001) wafer (U1), GaAs(111) wafer (U2), GaN/sapphire template (U3).
Mask pattern: stripemask (M1), dotmask (M2).
   Vj=70 μm/h, P_{NH3}=20 kPa, P_{HCl}=2 kPa.
   Result of Observation
M1: stripemask: Orientation inversion regions J continually occur on all mask stripes.
M2: dotmask: Orientation inversion regions J occur on all dots.
   [(3) In the Case of Tj3=920]
Undersubstrate: sapphire(0001) wafer (U1), GaAs(111) wafer (U2), GaN/sapphire template (U3).
Mask pattern: stripemask (M1), dotmask (M2).
   Vj=70 μm/h, P_{NH3}=20 kPa, P_{HCl}=2 kPa.
   Result of Observation
M1: stripemask: Orientation inversion regions J continually occur on all mask stripes.
M2: dotmask: Orientation inversion regions J occur on all dots.
   [(4) In the Case of Tj4=950]
Undersubstrate: sapphire(0001) wafer (U1), GaAs(111) wafer (U2), GaN/sapphire template (U3).
Mask pattern: stripemask (M1), dotmask (M2).
   Vj=70 μm/h, P_{NH3}=20 kPa, P_{HCl}=2 kPa.
   Result of Observation
M1: stripemask: Orientation inversion regions J continually occur on all mask stripes.
M2: dotmask: Orientation inversion regions J occur on all dots.
   [(5) In the Case of Tj5=970]
Undersubstrate: sapphire(0001) wafer (U1), GaAs(111) wafer (U2), GaN/sapphire template (U3).
Mask pattern: stripemask (M1), dotmask (M2).
   Vj=70 μm/h, P_{NH3}=20 kPa, P_{HCl}=2 kPa.
   Result of Observation
M1: stripemask: Orientation inversion regions J continually occur on all mask stripes.
M2: dotmask: Orientation inversion regions J occur on all mask dots.
   [(6) In the Case of Tj6=990]
Undersubstrate: sapphire(0001) wafer (U1), GaAs(111) wafer (U2), GaN/sapphire template (U3).
Mask pattern: stripemask (M1), dotmask (M2).
   Vj=70 μm/h, P_{NH3}=20 kPa, P_{HCl}=2 kPa.
   Result of Observation
M1: stripemask: Orientation inversion regions J continually occur on all mask stripes.
M2: dotmask: Orientation inversion regions J occur on all mask dots.
   [(7) In the Case of Tj6=1150]
Undersubstrate: sapphire(0001) wafer (U1), GaAs(111) wafer (U2), GaN/sapphire template (U3).
Mask pattern: stripemask (M1), dotmask (M2).
   Vj=70 μm/h, P_{NH3}=20 kPa, P_{HCl}=2 kPa.
   Result of Observation
M1: stripemask: Orientation inversion regions J occur on few mask stripes.
M2: dotmask: Orientation inversion regions J occur on few mask dots.

The results prove that formation of the inversion regions J depends upon the first temperature Tj. At some temperatures, inversion regions J happen on all masks. At other temperatures, few mask dots or stripes are covered with inversion regions J. Formation of on-mask inversion regions J will be examined afterward by changing conditions other than temperatures. The above results demonstrate that the first temperature Tj has a great influence on the formation of on-mask inversion regions J.

Tj7=1150 suppresses the undersubstrates (U1, U2, U3) with masks (M1, M2) from producing orientation inversion regions J. Tj7=1150 is not an appropriate temperature at the growing speed Vj=70 μm/h. Tj1=850 and Tj6=990 allow all or most of the mask dots or stripes to cause inversion regions J. An appropriated scope of the inversion region formation temperatures Tj at Vj=70 μm/h is a 140 degree range between 850 and 990.

Tj2=900 and Tj6=990 allow all the masks to induce inversion regions J. A more pertinent scope of the inversion region formation temperature at Vj=70 μm/h is 900 to 990.

### Embodiment 2

### Dependence on Growing Speeds Vj at a Temperature of 940

Embodiment 2 uses the same HVPE growth furnace as Embodiment 1. Embodiment 2 employs stripe/dotmasked GaAs(111) undersubstrates M1U2 and M2U2 prepared by forming an SiO₂ stripemask M1 or SiO₂ dotmask M2 on GaAs(111) undersubstrates U2. Embodiment 2 grows GaN crystals on the stripemasked and dotmasked undersubstrates by varying the growing speed Vj at a temperature of 940. Embodiment 2 investigates relations between the growing speed Vj and the facility of forming the orientation inversion regions J at 940.

The stripe/dotmasked undersubstrates M1U2 and M2U2 are laid on a susceptor in the HVPE reaction furnace. At an initial step, GaN buffer layers are grown on the undersubstrates for 15 minutes at a low temperature Tb of about Tb=500 by supplying HCl and NH₃ at a NH₃ partial pressure P_{NH}₃=0.2 atm (20 kPa) and an HCl partial pressure P_{HCl}=2×10⁻³ atm (0.2 kPa). The thicknesses of the buffer layers are about 60 nm.

The samples on the susceptor are heated up to an inversion region formation temperature Tj=940. GaN epitaxial layers and orientation inversion regions J are grown on exposed parts and masked parts respectively. The ammonia partial pressure is maintained to be a constant P_{NH3}=0.2 atm (20 kPa). The hydrochloride partial pressure P_{HCl} is varied for examining the dependence of the occurrence of inversion regions J upon P_{HCl}.

HCl partial pressure: P_{HCl}1=7×10⁻³ atm (0.7 kPa)
P_{HCl}2=1×10⁻² atm (1 kPa)
P_{HCl}3=1.5×10⁻² atm (1.5 kPa)
P_{HCl}4=2×10⁻² atm (2 kPa)
P_{HCl}5=3×10⁻² atm (3 kPa)
P_{HCl}6=4×10⁻² atm (4 kPa)

Embodiment 2 keeps the ammonia partial pressure P_{NH3}=0.2 atm (20 kPa) and the temperature Tj=940 and changes the hydrochloride partial pressure P_{HCl}. When the HCl partial pressure P_{HCl} is changed, the growing speed Vj is varied. Enhancement of the HCl partial pressure P_{HCl} raises the growing speed Vj. Variations of occurrence of orientation inversion regions J contingent on the growing speed Vj are examined.

(1) In the Case of P_{HCl}1=7×10⁻³ atm (0.7 kPa)

Growing speed Vj1=18 μm/h

Undersubstrate: GaAs wafer(U2), P_{NH3}=20 kPa, Tj=940.

Result of Observation

M1: stripemask: Orientation inversion regions J occur on few mask stripes.
M2: dotmask: Few mask dots carry orientation inversion regions J.
   (2) In the Case of P_{HCl}2=1×10⁻² atm (1 kPa)

Growing speed Vj2=32 μm/h

Undersubstrate: GaAs wafer(U2), P_{NH3}=20 kPa, Tj=940.

Result of Observation

M1: stripemask: Intermittent orientation inversion regions J discontinuously occur on mask stripes.
M2: dotmask: Orientation inversion regions J appear on most of the dots.
   (3) In the Case of P_{HCl}3=1.5×10⁻² atm (1.5 kPa)

Growing speed Vj3=48 μm/h

Undersubstrate: GaAs wafer(U2), P_{NH3}=20 kPa, Tj=940.

Result of Observation

M1: stripemask: Continual orientation inversion regions J occur all on mask stripes.
M2: dotmask: Orientation inversion regions J appear on all of the dots.
   (4) In the Case of P_{HCl}4=2×10⁻² atm (2 kPa)

Growing speed Vj4=70 μm/h

Undersubstrate: GaAs wafer(U2), P_{NH3}=20 kPa, Tj=940.

Result of Observation

M1: stripemask: Continual orientation inversion regions J occur on all mask stripes.
M2: dotmask: Orientation inversion regions J appear on all of the dots.
   (5) In the Case of P_{HCl}5=3×10⁻² atm (3 kPa)

Growing speed Vj5=102 μm/h

Undersubstrate: GaAs wafer(U2), P_{NH3}=20 kPa, Tj=940.

Result of Observation

M1: stripemask: Continual orientation inversion regions J occur on all mask stripes.
M2: dotmask: Orientation inversion regions J appear on all of the dots.
   (6) In the Case of P_{HCl}6=4×10⁻² atm (4 kPa)

Growing speed Vj6=138 μm/h

Undersubstrate=GaAs wafer(U2), P_{NH3}=20 kPa, Tj=940.

Result of Observation

M1: stripemask: Orientation inversion regions J occur on few mask stripes.
M2: dotmask: Orientation inversion regions J appear on few dots.

The above observation teaches us the following facts. Occurrence of c-axis inversion regions J depends upon the growing speed Vj. A slower growing speed than 18 μm/h suppresses orientation inversion regions J from happening. A faster growing speed than 138 μm/h also suppresses orientation inversion regions J from occurring.

An optimum growing speed Vj for producing orientation inversion regions J on masks ranges from 25 μm/h to 120 μm/h at 940. The lowest limit 25 μm/h and the highest limit 120 μm/h are calculated by averaging the marginal appropriate speeds of making sufficient orientation inversion regions J and the neighboring inappropriate speeds of inducing few inversion regions J.

### Embodiment 3

### Dependence on Growing Speeds at a Temperature of 1030

Repetitions of trials of Embodiments 1 and 2 suggest the inventors that the facility of inducing inversion regions J depends strongly upon the temperature Tj firstly and depends upon the growing speeds Vj at the temperature Tj secondarily. Embodiment 3 investigates dependence of inversion region occurrence upon growing speeds at a temperature of 1030 higher than Embodiment 2 (940).

Embodiment 3 uses the same HVPE growth furnace as Embodiment 1. Embodiment 3 employs stripe/dotmasked GaAs(111) undersubstrates M1U2 and M2U2 prepared by forming an SiO₂ stripemask M1 or an SiO₂ dotmask M2 on GaAs(111) undersubstrates U2. Embodiment 3 grows GaN crystals on the stripemasked and dotmasked undersubstrates by varying the growing speed at a temperature of 1030 different from Embodiment 2 (940). Embodiment 3 investigates relations between the growing speed and the facility of forming the orientation inversion regions J at 1030.

The stripe/dotmasked undersubstrates M1U2 and M2U2 are laid on a susceptor in the HVPE reaction furnace. At an initial step, GaN buffer layers are grown on the undersubstrates for 15 minutes at a low temperature of about 500 by supplying HCl and NH₃ at a NH₃ partial pressure P_{NH3}=0.2 atm (20 kPa) and an HCl partial pressure P_{HCl}=2×10⁻³ atm (0.2 kPa). Thicknesses of the buffer layers are about 60 nm.

The samples on the susceptor are heated up to an inversion region formation temperature of Tj=1030. GaN epitaxial layers and orientation inversion regions J are grown on exposed parts and masked parts respectively. The ammonia partial pressure is maintained to be a constant P_{NH3}=0.2 atm (20 kPa). The hydrochloride partial pressure P_{HCl} is varied for examining the dependence of the occurrence of inversion regions J upon P_{HCl}.

HCl partial pressure: P_{HCl}1=7×10⁻³ atm (0.7 kPa)
P_{HCl}2=1×10⁻² atm (1 kPa)
P_{HCl}3=1.5×10⁻² atm (1.5 kPa)
P_{HCl}4=2×10⁻² atm (2 kPa)
P_{HCl}5=4×10⁻² atm (4 kPa)
P_{HCl}6=6×10⁻² atm (6 kPa)
P_{HCl}7=8×10⁻² atm (8 kPa)

Although the ammonia (NH₃) partial pressure P_{NH3} is constant, the growing speed is changed by varying the hydrochloride (HCl) partial pressure P_{HCl}. An increase of the HCl partial pressure enhances the growing speed Vj. Embodiment 3 examines the dependence of appearance of the inversion regions J upon the growing speed Vj.

(1) In the Case of P_{HCl}1=7×10⁻³ atm (0.7 kPa)

Growing speed Vj1=22 μm/h

Undersubstrate: GaAs wafer(U2), P_{NH3}=20 kPa, Tj=1030.

Result of Observation

M1: stripemask: Orientation inversion regions J occur on few mask stripes.
M2: dotmask: Few mask dots carry orientation inversion regions J.
   (2) In the Case of P_{HCl}2=1×10⁻² atm (1 kPa)

Growing speed Vj2=38 μm/h

Undersubstrate: GaAs wafer(U2), P_{NH3}=20 kPa, Tj=1030.

Result of Observation

M1: stripemask: Intermittent orientation inversion regions J discontinuously occur on few mask stripes.
M2: dotmask: Orientation inversion regions J appear on few dots.
   (3) In the Case of P_{HCl}3=1.5×10⁻² atm (1.5 kPa)

Growing speed Vj3=62 μm/h

Undersubstrate: GaAs wafer(U2), P_{NH3}=20 kPa, Tj=1030.

Result of Observation

M1: stripemask: Orientation inversion regions J intermittently occur all on mask stripes.
M2: dotmask: Orientation inversion regions J appear on most of the dots.
   (4) In the case of P_{HCl}4=2×10⁻² atm (2 kPa)

Growing speed Vj4=85 μm/h

Undersubstrate: GaAs wafer(U2), P_{NH3}=20 kPa, Tj=1030.

Result of Observation

M1: stripemask: Orientation inversion regions J intermittently occur on all mask stripes.
M2: dotmask: Orientation inversion regions J appear on most of the dots.
   (5) In the Case of P_{HCl}5=4×10⁻² atm (4 kPa)

Growing speed Vj5=132 μm/h

Undersubstrate: GaAs wafer(U2), P_{NH3}=20 kPa, Tj=1030.

Result of Observation

M1: stripemask: Orientation inversion regions J intermittently occur on all mask stripes.
M2: dotmask: Orientation inversion regions J appear on most of the dots.
   (6) In the Case of P_{HCl}6=6×10⁻² atm (6 kPa)

Growing speed Vj6=158 μm/h

Undersubstrate: GaAs wafer(U2), P_{NH3}=20 kPa, Tj=1030.

Result of Observation

M1: stripemask: Orientation inversion regions J intermittently occur on mask stripes.
M2: dotmask: Orientation inversion regions J appear on most of the dots.
   (7) In the Case of P_{HCl}7=8×10⁻² atm (8 kPa)

Growing speed Vj7=236 μm/h

Undersubstrate=GaAs wafer(U2), P_{NH3}=20 kPa, Tj=1030.

Result of Observation

M1: stripemask: Orientation inversion regions J occur on few mask stripes.
M2: dotmask: Orientation inversion regions J appear on few dots.

The above results show the inversion region occurrence dependence upon the growing speed Vj. It is again confirmed that the change of the growing speed Vj varies the occurrence of the c-axis inversion regions J. However, it is noticed that Embodiment 3, which grows GaN at Tj=1030, has inversion region appearance dependence upon the growing speed Vj which differs from Embodiment 2 growing GaN at Tj=940. In Embodiment 3 with a high temperature of Tj=1030, low growing speeds less than 38 μm/h suppress inversion regions J from happening on masks. Even a high growing speed of 158 μm/h allows many orientation inversion regions J to happen on masks. Further high growing speeds more than 236 μm/h decrease occurrence of on-mask orientation inversion regions J in Embodiment 3 of Tj=1030.

At a growing temperature of Tj=1030, an appropriate growing speed range of producing orientation inversion regions J is from 50 μm/h and 197 μm/h. It is confirmed that the pertinent growing speed range (50-197 μm/h) at Tj=1030 (Embodiment 3) is upward shifted from the appropriate growing speed range (25-120 μm/h) at Tj=940 (Embodiment 2).

### Embodiment 4

### Inversion Region Occurrence Dependence Upon Growing Speed Vj at a Temperature of Tj=960

Embodiment 3 has clarified an appropriate growing speed range for inducing orientation inversion regions on masks at 1030. Embodiments 1 and 2 suggest that lower temperatures than 1030 are more pertinent for making orientation inversion regions J on all masks. Therefore Embodiment 4 investigates the relation between the growing speed Vj and the inversion region occurrence facility at a low temperature close to 940 of Embodiment 2.

Embodiment 4 uses the same HVPE growth furnace as Embodiment 1. Embodiment 3 employs stripe/dotmasked GaAs(111) undersubstrates M1U2 and M2U2 prepared by forming an SiO₂ stripemask M1 or an SiO₂ dotmask M2 on GaAs(111) undersubstrates U2. Embodiment 4 grows GaN crystals on the stripemasked and dotmasked undersubstrates by varying the growing speed at temperatures different from Embodiment 2. Embodiment 4 investigates relations between the growing speed and the facility of forming the orientation inversion regions J.

The stripe/dot-masked GaAs undersubstrates (M1U2, M2U2) are placed upon a susceptor in the HVPE furnace. At an initial stage, Embodiment 4 makes GaN buffer layers on the undersubstrate (M1U2, M2U2) for 15 minutes at a low temperature Tb of about Tb=500 under an ammonia partial pressure P_{NH3}=0.2 atm (20 kPa) and a hydrochloride partial pressure P_{HCl}=2×10⁻³(0.2 kPa). The thickness of the GaN buffer layers is about 60 nm.

Embodiment 4 heats the susceptor and specimens up to an inversion region formation temperature Tj of Tj=960. The ammonia partial pressure is maintained to be a constant P_{NH3}=0.2 atm (20 kPa). The hydrochloride partial pressure P_{HCl} is varied for examining how on-mask occurrence of orientation inversion regions J changes as a function of P_{HCl}.

HCl partial pressure: P_{HCl}1=7×10⁻³ atm (0.7 kPa)
P_{HCl}2=1×10⁻² atm (1 kPa)
P_{HCl}3=1.5×10⁻² atm (1.5 kPa)
P_{HCl}4=2×10⁻² atm (2 kPa)
P_{HCl}5=2.5×10⁻² atm (2.5 kPa)
P_{HCl}6=3×10⁻² atm (3 kPa)
P_{HCl}7=4×10⁻² atm (4 kPa)

Maintaining P_{NH3}=0.2 atm (20 kPa), Embodiment 4 changes the growing speed by varying the hydrochloride partial pressure P_{HCl}. An increase of the hydrochloride partial pressure P_{HCl} raises the growing speed Vj. Embodiment 4 inspects how the occurrence of orientation inversion regions J depends upon the growing speed Vj.

(1) In the Case of P_{HCl}1=7×10⁻³ atm (0.7 kPa)

Growing speed Vj1=20 μm/h

Undersubstrate: GaAs wafer(U2), P_{NH3}=20 kPa, Tj=960.

Result of Observation

M1: stripemask: Orientation inversion regions J occur on few mask stripes.
M2: dotmask: Few mask dots carry orientation inversion regions J.
   (2) In the Case of P_{HCl}2=1×10⁻² atm (1 kPa)

Growing speed Vj2=28 μm/h

Undersubstrate: GaAs wafer(U2), P_{NH3}=20 kPa, Tj=960.

Result of Observation

M1: stripemask: Orientation inversion regions J occur on few mask stripes.
M2: dotmask: Few mask dots carry orientation inversion regions J.
   (3) In the Case of P_{HCl}3=1.5×10⁻² atm (1.5 kPa)

Growing speed Vj3=42 μm/h

Undersubstrate: GaAs wafer(U2), P_{NH3}=20 kPa, Tj=960.

Result of Observation

M1: stripemask: Intermittent orientation inversion regions J dottedly occur on mask stripes.
M2: dotmask: Orientation inversion regions J appear on most of the mask dots.
   (4) In the Case of P_{HCl}4=2×10⁻² atm (2 kPa)

Growing speed Vj4=65 μm/h

Undersubstrate: GaAs wafer(U2), P_{NH3}=20 kPa, Tj=960.

Result of Observation

M1: stripemask: Orientation inversion regions J continually occur on mask stripes.
M2: dotmask: Orientation inversion regions J appear on all mask dots.
   (5) In the Case of P_{HCl}5=2.5×10⁻² atm (2.5 kPa)

Growing speed Vj5=110 μm/h

Undersubstrate: GaAs wafer(U2), P_{NH3}=20 kPa, Tj=960.

Result of Observation

M1: stripemask: Orientation inversion regions J continually occur on mask stripes.
M2: dotmask: Orientation inversion regions J appear on every mask dot.
   (6) In the Case of P_{HCl}6=3×10⁻² atm (3 kPa)

Growing speed Vj6=130 μm/h

Undersubstrate: GaAs wafer(U2), P_{NH3}=20 kPa, Tj=960.

Result of Observation

M1: stripemask: Orientation inversion regions J intermittently occur on mask stripes.
M2: dotmask: Orientation inversion regions J appear on most mask dots.
   (7) In the Case of P_{HCl}7=4×10⁻² atm (4 kPa)

Growing speed Vj7=150 μm/h

Undersubstrate: GaAs wafer(U2), P_{NH3}=20 kPa, Tj=960.

Result of Observation

M1: stripemask: Orientation inversion regions J occur on few mask stripes.
M2: dotmask: Orientation inversion regions J appear on few mask dots.

The above results teach us that a change of the growing speed Vj varies the occurrence of the c-axis inversion regions J.

The dependence of the occurrence of the orientation inversion regions J upon the growing speed Vj at Tj=960 is different from the case of Tj=940 (Embodiment 2). Embodiment 4 grows GaN at a temperature 20 degrees higher than Embodiment 2. In Embodiment 4, a low growing speed of 42 μm/h invites orientation inversion regions almost all of the masks (M1, M2). But growing speeds lower than 28 μm/h suppress orientation inversion regions from happening. In Embodiment 4, high growing speed of Vj6=130 μm/h causes sufficient orientation inversion regions J on masks. Further high growing speed of Vj7=150 μm/h is too fast to make enough orientation inversion regions J on masks.

An appropriate range at Tj=960 of inviting c-axis inversion regions on masks is 35 μm/h to 140 μm/h. The marginal values (35, 140 μm/h) are determined by averaging the speed causing sufficient inversion regions J on most masks and the speed making poor inversion regions on few masks. The appropriate range (35 μm/h-140 μm/h) at Tj=960 (Embodiment 4) is slightly higher than the appropriate range (25 μm/h-120 μm/h) at Tj=940 (Embodiment 2).

At 960 (Embodiment 4), growing speeds Vj4=65 μm/h and Vj5=110 μm/h yield sufficient inversion regions J on all masks. The results show that Tj=960 (Embodiment 4) is stronger than Tj=1030 (Embodiment 3) in causing inversion regions J.

### Embodiment 5

### Inversion Region Occurrence Dependence Upon Growing Speed Vj at a Temperature of Tj=920

Embodiments 2, 3 and 4 have clarified an appropriate growing speed range for inducing orientation inversion regions on masks at 940, 1030 and 960 respectively. Embodiment 5 investigates the relation between the growing speed Vj and the inversion region occurrence facility at a temperature Tj=920 close to 940 of Embodiment 2.

Embodiment 5 uses the same HVPE growth furnace as Embodiment 1. Embodiment 5 employs stripe/dotmasked GaAs(111) undersubstrates M1U2 and M2U2 prepared by forming an SiO₂ stripemask M1 or an SiO₂ dotmask M2 on GaAs(111) undersubstrates U2. Embodiment 5 grows GaN crystals on the stripemasked and dotmasked undersubstrates by varying the growing speed at a temperatures of 920. Embodiment 5 investigates relations between the growing speed and the facility of forming the orientation inversion regions J at 920.

The stripe/dot-masked GaAs undersubstrates (M1U2, M2U2) are placed upon a susceptor in the HVPE furnace. At an initial stage, Embodiment 5 makes GaN buffer layers on the undersubstrate (M1U2, M2U2) for 15 minutes at a low temperature Tb of about Tb=500 under an ammonia partial pressure P_{NH3}=0.2 atm (20 kPa) and a hydrochloride partial pressure P_{HCl}=2×10⁻³ (0.2 kPa). The thickness of the GaN buffer layers is about 60 nm.

Embodiment 5 heats the susceptor and specimens up to an inversion region formation temperature Tj of Tj=920. The ammonia partial pressure is maintained to be a constant P_{NH3}=0.2 atm (20 kPa). The hydrochloride partial pressure P_{HCl} is varied for examining how on-mask occurrence of orientation inversion regions J changes as a function of P_{HCl}.

HCl partial pressure: P_{HCl}1=7×10⁻³ atm (0.7 kPa)
P_{HCl}2=1×10⁻² atm (1 kPa)
P_{HCl}3=1.5×10⁻² atm (1.5 kPa)
P_{HCl}4=2×10⁻² atm (2 kPa)
P_{HCl}5=4×10⁻² atm (4 kPa)
P_{HCl}6=5×10⁻² atm (5 kPa)

Maintaining P_{NH3}=0.2 atm (20 kPa) and Tj=920, Embodiment 5 changes the growing speed by varying the hydrochloride partial pressure P_{HCl}. Increase of the hydrochloride partial pressure P_{HCl} raises the growing speed Vj. Embodiment 5 inspects how the occurrence of orientation inversion regions J depends upon the growing speed Vj.

(1) In the Case of P_{HCl}1=7×10⁻³ atm (0.7 kPa)

Growing speed Vj1=14 μm/h

Undersubstrate: GaAs wafer(U2), P_{NH3}=20 kPa, Tj=920.

Result of Observation

M1: stripemask: Orientation inversion regions J occur on few mask stripes.
M2: dotmask: Few mask dots carry orientation inversion regions J.
   (2) In the Case of P_{HCl}2=1×10⁻² atm (1 kPa)

Growing speed Vj2=36 μm/h

Undersubstrate: GaAs wafer(U2), P_{NH3}=20 kPa, Tj=920.

Result of Observation

M1: stripemask: Continual orientation inversion regions J occur on mask stripes.
M2: dotmask: All mask dots carry orientation inversion regions J.
   (3) In the Case of P_{HCl}3=1.5×10⁻² atm (1.5 kPa)

Growing speed Vj3=55 μm/h

Undersubstrate: GaAs wafer(U2), P_{NH3}=20 kPa, Tj=920.

Result of Observation

M1: stripemask: Continual orientation inversion regions J occur on mask stripes.
M2: dotmask: Orientation inversion regions J appear on all of the mask dots.
   (4) In the Case of P_{HCl}4=2×10⁻² atm (2 kPa)

Growing speed Vj4=75 μm/h

Undersubstrate: GaAs wafer(U2), P_{NH3}=20 kPa, Tj=920.

Result of Observation

M1: stripemask: Continual orientation inversion regions J occur on mask stripes.
M2: dotmask: Orientation inversion regions J appear on all mask dots.
   (5) In the Case of P_{HCl}5=4×10⁻² atm (4 kPa)

Growing speed Vj5=110 μm/h

Undersubstrate: GaAs wafer(U2), P_{NH3}=20 kPa, Tj=920.

Result of Observation

M1: stripemask: Orientation inversion regions J intermittently occur on mask stripes.
M2: dotmask: Orientation inversion regions J appear on all mask dots.
   (6) In the Case of P_{HCl}6=5×10⁻² atm (5 kPa)

Growing speed Vj6=130 μm/h

Undersubstrate: GaAs wafer(U2), P_{NH3}=20 kPa, Tj=920.

Result of Observation

M1: stripemask: Orientation inversion regions J occur on few mask stripes.
M2: dotmask: Orientation inversion regions J appear on few mask dots.

The above results teach us that the change of the growing speed Vj varies the occurrence of the c-axis inversion regions J.

The dependence of the occurrence of the orientation inversion regions J upon the growing speed Vj at Tj=920 (Embodiment 5) is different from the case of Tj=940 (Embodiment 2). Embodiment 5 grows GaN at a temperature 20 degrees lower than Embodiment 2. In Embodiment 5, a low growing speed of 36 μm/h invites orientation inversion regions onto all of the masks (M1, M2). But growing speeds lower than 14 μm/h suppress orientation inversion regions from happening. In Embodiment 5, high growing speed of Vj5=110 μm/h causes sufficient orientation inversion regions J on masks. Further high growing speed of Vj6=130 μm/h is too fast to make enough orientation inversion regions J on masks.

An appropriate range of inviting c-axis inversion regions on masks is 25 μm/h to 120 μm/h (Embodiment 5) at Tj=920. The marginal values (25, 120 μm/h) are determined by averaging the speed causing sufficient inversion regions J on most masks and the speed making poor inversion regions on few masks. The appropriate range (25 μm/h-120 μm/h) at Tj=920 (Embodiment 5) is slightly lower than the appropriate range (35 μm/h-140 μm/h) at Tj=960 (Embodiment 4).

At 920 (Embodiment 5), growing speeds Vj=36 μm/h, 55 μm/h and 77 μm/h yield sufficient inversion regions J on all masks. The results show that Tj=920 (Embodiment 5) is more effective than Tj=1030 (Embodiment 3) in causing inversion regions J.

### Embodiment 6

### Thick GaN Crystal Growth at Te=1050 Succeeding Inversion Regions Formation

Embodiments 1, 2, 3, 4 and 5 grow the inversion regions J on masks and epitaxial GaN crystals on exposed parts in the first growth. The purpose of the first growth is to make the orientation inversion regions J on masks as defect accumulating regions H. The second growth denotes thick GaN crystal growth succeeding the first growth. Embodiment 6, which grows thick GaN crystals, includes the first growth and the second growth. Embodiment 6 employs the same HVPE furnace as Embodiment 1. Embodiment 6 adopts a sapphire (0001) single crystal wafers U1 as undersubstrates.

A dotmask M2 (FIG. 10(1)) is formed on a sapphire undersubstrate U1. A stripemask M1 (FIG. 8(1)) is formed on another sapphire undersubstrate U1. Then two kinds of masked undersubstrates M1U1 and M2U1 are prepared. The buffer layer formation and the first growth are done on the masked undersubstrates M1U1 and M2U1 of Embodiment 6.

The masked undersubstrates are placed upon a susceptor in the HVPE reaction furnace. At an initial step, Embodiment 6 grows GaN buffer layers for 15 minutes at a low temperature of about Tb=500 at P_{NH3}=0.2 atm (20 kPa) and P_{HCl}=2×10⁻³ atm (0.2 kPa). The ammonia/hydrochloride ratio is P_{NH3}/P_{HCl}=100 at the buffer layer growth step. The thickness of the buffer layers is about 60 nm.

The susceptor and specimens are heated up to a first growth temperature Tj=950 for producing orientation inversion regions J on masks. At the first growth, Embodiment 6 grows GaN on the undersubstrates M1U1 and M2U1 at Tj=950, P_{NH3}=0.2 atm (20 kPa) and P_{HCl}=2×10⁻² atm (2 kPa) for 45 minutes for making inversion regions J on masks and GaN crystals on exposed parts. The ammonia/hydrochloride ratio is P_{NH3}/P_{HCl}=10 at the first growth step for making inversion regions J.

Following the inversion region formation, Embodiment 6 grows epitaxial thick GaN crystals on the GaN/mask/undersubstrates at a second growth temperature of Te=1050, P_{N H3}=0.2 atm (20 kPa) and P_{HCl}=3×10⁻² atm (3 kPa). The ammonia/hydrochloride ratio is P_{NH3}/P_{HCl}=6.7 at the second growth step for making thick GaN crystals. The growth time is 15 hours. Embodiment 6 cools the furnace, takes specimens out of the furnace and obtains 1.5 mm thick GaN crystals.

The GaN crystals are observed by a stereoscopic microscope and a scanning electron microscope (SEM). On-dotmask grown GaN crystals have dotted cavities just above the mask dots. On-stripemask grown GaN crystals have shallow parallel cavities just on the mask stripes. The positions of the cavities correctly correspond to the positions of the masks. The cavities are composed of facets. There are other shallower facets at the bottoms of the cavities.

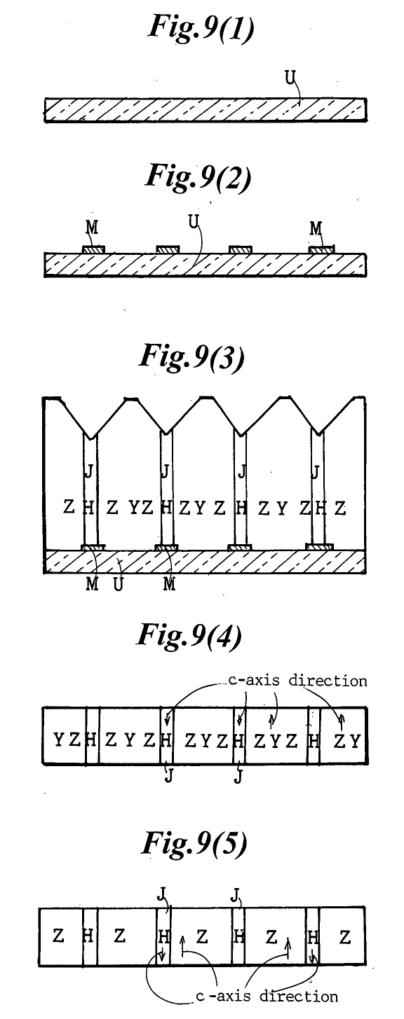

Embodiment 6 removes the sapphire undersubstrates (U1) by grinding and obtains freestanding GaN substrates. Surfaces of the freestanding GaN crystals are ground and polished into both-surface mirror flat GaN wafers (FIG. 9(4)). The GaN crystals are transparent for visible light. The GaN crystals look like a uniform glass for human eye sight. Human eye sight cannot discern inner structures of the GaN crystals.

Embodiment 6 observes surfaces of the polished stripemask/dotmask-grown GaN substrates by an optical microscope and cathode luminescence (CL).

It is confirmed that the on-stripemask GaN substrates have parallel cavities with a 20 μm width regularly aligning at a 300 μm pitch. This corresponds to the stripemask (s=30 μm, p=300 μm) with accuracy. The cavities originate from the occurrence of {11-2-6} facets on masks. The existence of {11-2-6} facets on masks proves that the on-mask regions are orientation inversion regions J. The CL observation demonstrates that the on-stripemask GaN substrates have an HZYZHZYZ . . . structure as shown in FIG. 8(2). It is confirmed that defect accumulating regions H are generated on mask stripes and the defect accumulating regions H are orientation inversion regions J.

The optical microscope observes that cavities with a diameter of 30 μm to 40 μm appear at spots aligning at a 300 μm pitch in six fold symmetry on the on-dotmask (M2) GaN substrates. The positions of the cavities correspond to the spots of mask dots (t=50 μm, p=300 μm). The on-dotmask GaN substrate reveals a concentric HZY-structure composed of defect accumulating regions H, low defect density single crystal regions Z and a C-plane growth region Y.

The CL sees a defect accumulating region H as a dark spot. Threading dislocation density is measured by counting dark spots in a definite area on a CL image. The defect accumulating regions H have a high threading dislocation density of about 10⁷ cm⁻² to about 10⁸ cm⁻². The low defect density single crystal regions Z sandwiched between neighboring defect accumulating regions H and H have a low threading dislocation density of about 1×10⁵ cm⁻².

It is confirmed that the crystal regions held between defect accumulating regions H are single crystals Z enjoying sufficiently low defect density. The produced GaN substrates are non-uniform substrates composed of H, Z and Y.

The present invention enables device makers to fabricate laser diodes on the low defect density single crystal regions Z. The present invention succeeds in making low defect density GaN substrates capable of producing laser diodes of high quality. The GaN substrates do not have uniformly low defect density. The GaN substrates of the present invention have both narrow defect accumulating regions H and wide low defect density single crystal regions Z. The present invention serves excellent GaN substrates suitable for producing photodevices of high quality.

What we claim is:

1. A method of growing a GaN crystal comprising the steps of:
preparing an undersubstrate;
covering the undersubstrate partially with masks capable of prohibiting GaN from epitaxially growing;
producing narrow masked parts and wide exposed parts on the undersubstrate;
growing GaN crystals in vapor phase on the undersubstrate on a first growth condition of maintaining the GaN crystals at a first growth temperature Tj from 900° C. to 990° C.;
making GaN crystals having a definite c-axis on exposed parts;
prohibiting GaN from growing on masked parts;
inducing facets starting from edges of the masks and rising to a top of the GaN crystals on exposed parts;
maintaining the facets;
making low defect density GaN crystals on the exposed parts;
inducing beaks midway on facets facing across a mask, the beaks having a c-axis inverse to the c-axis of the GaN crystals on the exposed parts;
making low defect density single crystal regions Z covered with the facets on the exposed parts;
unifying the beaks above the masks; and
making polarity inversion regions J on piling GaN crystals on the unified beaks, the polarity inversion regions J having a c-axis inverse to the c-axis of the GaN crystals on the exposed parts.

2. The method as claimed in claim 1, wherein the first growth condition is a temperature between 920° C. and 960° C. for making inversion regions J.

3. A method of growing a GaN crystal comprising the steps of:
preparing an undersubstrate;
covering the undersubstrate partially with masks capable of prohibiting GaN from epitaxially growing;
producing narrow masked parts and wide exposed parts on the undersubstrate;
growing GaN crystals in vapor phase on the undersubstrate on a first growth condition of determining a first growth temperature Tj(K) in absolute temperature unit and a growing speed Vj (μm/h) satisfying inequalities a₁/Tj+b₁<Vj<a₂/Tj+b₂ where a₁=−4.39×10⁵ (Kμm/h), b₁=3.87×10² (μm/h), a₂=−7.36×10⁵ (Kμm/h) and b₂=7.37×10²(μm/h), at an initial stage;
making GaN crystals having a definite c-axis on exposed parts;
prohibiting GaN from growing on masked parts;
inducing facets starting from edges of the masks and rise to a top of the GaN crystals on exposed parts;
maintaining the facets,
inducing beaks midway on facets facing across a mask, the beaks having a c-axis inverse to the c-axis of the gallium nitride crystals on the exposed parts;
making low defect density single crystal regions Z covered with the facets on the exposed parts;
unifying the beaks above the masks; and
making polarity inversion regions J on piling gallium nitride crystals on the unified beaks, the polarity inversion regions J having a c-axis inverse to the c-axis of the gallium nitride crystals on the exposed parts.

4. The method as claimed in claim 1, wherein a GaN buffer layer with a thickness between 30 nm and 200 nm is formed at a low temperature Tb from 400° C. to 600° C. on the exposed parts of the undersubstrate before GaN epitaxial growth.

5. The method as claimed in claim 2, wherein a GaN buffer layer with a thickness between 30 nm and 200 nm is formed at a low temperature Tb from 400° C. to 600° C. on the exposed parts of the undersubstrate before GaN epitaxial growth.

6. The method as claimed in claim 3, wherein a GaN buffer layer with a thickness between 30 nm and 200 nm is formed at a low temperature Tb from 400° C. to 600° C. on the exposed parts of the undersubstrate before GaN epitaxial growth.

7. The method as claimed in claim 1, wherein the undersubstrate is one of sapphire single crystal wafer, an Si single crystal wafer, an SiC single crystal wafer, a GaN single crystal wafer, GaAs single crystal wafer and GaN/sapphire template.

8. The method as claimed in claim 2, wherein the undersubstrate is one of sapphire single crystal wafer, an Si single crystal wafer, an SiC single crystal wafer, a GaN single crystal wafer, GaAs single crystal wafer and GaN/sapphire template.

9. The method as claimed in claim 3, wherein the undersubstrate is one of sapphire single crystal wafer, an Si single crystal wafer, an SiC single crystal wafer, a GaN single crystal wafer, GaAs single crystal wafer and GaN/sapphire template.

10. The method as claimed in claim 4, wherein the undersubstrate is one of sapphire single crystal wafer, an Si single crystal wafer, an SiC single crystal wafer, a GaN single crystal wafer, GaAs single crystal wafer and GaN/sapphire template.

11. The method as claimed in claim 5, wherein the undersubstrate is one of sapphire single crystal wafer, an Si single crystal wafer, an SiC single crystal wafer, a GaN single crystal wafer, GaAs single crystal wafer and GaN/sapphire template.

12. The method as claimed in claim 6, wherein the undersubstrate is one of sapphire single crystal wafer, an Si single crystal wafer, an SiC single crystal wafer, a GaN single crystal wafer, GaAs single crystal wafer and GaN/sapphire template.

13. The method as claimed in claim 1, wherein the method of vapor phase growth is a hydride vapor phase epitaxy (HVPE) method.

14. The method as claimed in claim 2, wherein the method of vapor phase growth is a hydride vapor phase epitaxy (HVPE) method.

15. The method as claimed in claim 3, wherein the method of vapor phase growth is a hydride vapor phase epitaxy (HVPE) method.

16. The method as claimed in claim 4, wherein the method of vapor phase growth is a hydride vapor phase epitaxy (HVPE) method.

17. A method of growing a GaN crystal comprising the steps of:
preparing an undersubstrate;
covering the undersubstrate partially with masks capable of prohibiting GaN from epitaxially growing;
producing narrow masked parts and wide exposed parts on the undersubstrate;
growing GaN crystals in vapor phase on the undersubstrate on a first growth condition of maintaining the GaN crystals at a first growth temperature Tj from 900° C. to 990° C.;
making GaN crystals having a definite c-axis on exposed parts;
prohibiting GaN from growing on masked parts;
inducing facets starting from edges of the masks and rise to a top of the GaN crystals on exposed parts;
maintaining the facets;
inducing beaks midway on facets facing across a mask, the beaks having a c-axis inverse to the c-axis of the GaN crystals on the exposed parts;
making low defect density single crystal regions Z covered with the facets on the exposed parts;
unifying the beaks above the masks;
making polarity inversion regions J on piling GaN crystals on the unified beaks;
growing a thick GaN crystal on a second growth condition of maintaining a second growth temperature Te higher than 990° C. on the GaN crystal with inversion regions J on the masks;
growing low defect density single crystal regions Z and C-plane growth regions Y having decreasing dislocation densities on exposed parts;
growing inversion regions J having an increasing dislocation density as defect accumulating regions H on the masked parts; and
maintaining the facets till the end of growth.

18. A method of growing a GaN crystal comprising the steps of:
preparing an undersubstrate;
covering the undersubstrate partially with masks capable of prohibiting GaN from epitaxially growing;
producing narrow masked parts and wide exposed parts on the undersubstrate;
growing GaN crystals in vapor phase on the undersubstrate on a first growth condition of determining a first growth temperature Tj(K) in absolute temperature unit and a growing speed Vj (μm/h) satisfying inequalities a₁/Tj+b₁<Vj<a₂/Tj+b₂ where a₁=−4.39×10⁵ (Kμm/h), b₁=3.87×10² (μm/h), a₂=−7.36×10⁵ (Kμm/h) and b₂=7.37×10² (μm/h), at an initial stage;
making GaN crystals having a definite c-axis on exposed parts;
prohibiting GaN from growing on masked parts;
inducing facets starting from edges of the masks and rising to a top of the GaN crystals on exposed parts;
maintaining the facets,
inducing beaks midway on facets facing across a mask, the beaks having a c-axis inverse to the c-axis of the GaN crystals on the exposed parts;
making low defect density single crystal regions Z covered with the facets on the exposed parts;
unifying the beaks above the masks;
making polarity inversion regions J on piling GaN crystals on the unified beaks;
growing a thick GaN crystal on a second condition of maintaining a second growth temperature Te higher than 990° C. on the gallium nitride crystal with inversion regions J on masks; and
maintaining the facets till the end of growth.

19. The method as claimed in claim 17, wherein the second growth temperature Te is 1000° C. to 1200° C.

20. The method as claimed in claim 18, wherein the second growth temperature Te is 1000° C. to 1200° C.
